(19) United States
(12) Patent Application Publication
(10) Pub. No.: US 2025/0081742 A1
(43) Pub. Date: Mar. 6, 2025

(54) DISPLAY PANEL AND METHOD OF FABRICATING THE SAME

(71) Applicant: Samsung Display Co., Ltd., Yongin-si (KR)

(72) Inventors: HYUNEOK SHIN, Yongin-si (KR); YOUNGMO KOO, Yongin-si (KR)

(73) Assignee: Samsung Display Co., Ltd., Yongin-si (KR)

(21) Appl. No.: 18/630,095

(22) Filed: Apr. 9, 2024

(30) Foreign Application Priority Data
Sep. 4, 2023 (KR) 10-2023-0117096

(51) Int. Cl. H10K 59/122; H10K 59/12; H10K 59/35; H10K 59/80

(52) U.S. Cl. CPC H10K 59/122; H10K 59/1201; H10K 59/353; H10K 59/873

(57) ABSTRACT

A display panel includes a pixel definition layer having a plurality of emission openings, a partition wall having a plurality of partition openings and having conductivity, a first emission element in a first emission opening and including a first light emitting material, and a second emission element in a second emission opening and including a second light emitting material. A contact area between the first emission layer and the partition wall and a contact area between the second emission layer and the partition wall are different from each other.

### CROSS-REFERENCE TO RELATED APPLICATION(S)

This application claims priority to and benefits of Korean Patent Application No. 10-2023-0117096 under 35 U.S.C. § 119, filed on Sep. 4, 2023, in the Korean Intellectual Property Office (KIPO), the entire contents of which are incorporated herein by reference.

### BACKGROUND

### 1. Technical Field

The disclosure relates to a display panel with improved display quality and a display device including the same.

### 2. Description of the Related Art

A display panel, which displays an image, is included in a display device, such as a television, a monitor, a smart phone, and a tablet computer, which provides images to users. Various display panels have been developed such as liquid crystal display panels, organic light emitting display panels, electro-wetting display panels, and electrophoretic display panels.

An organic light emitting display panel may include an anode, a cathode, and an emission pattern. The emission pattern may be divided for each emission region, and the cathode may provide a common voltage to each emission region.

### SUMMARY

The disclosure provides a display panel having increased display quality and a method of fabricating the same in which method an emission element is formed without using a metal mask.

According to an embodiment of the disclosure, a display panel may include a base layer, a pixel definition layer on the base layer and including a plurality of emission openings that are spaced apart from each other, a partition wall on the pixel definition layer and including a plurality of partition openings that overlap the plurality of emission openings in a plan view, the partition wall having conductivity, a first emission element in a first emission opening of the plurality of emission openings, the first emission element including a first anode, a first emission layer on the first anode and including a light emitting material that generates light of a first color, and a first cathode on the first emission layer and coupled to the partition wall, and a second emission element in a second emission opening of the plurality of emission openings, the second emission element including a second anode, a second emission layer on the second anode and including a light emitting material that generates light of a second color different from the first color, and a second cathode on the second emission layer and coupled to the partition wall. A contact area between the first emission layer and the partition wall and a contact area between the second emission layer and the partition wall may be different from each other.

In an embodiment, a cross-sectional shape of a portion of the first emission layer contacting the partition wall and a cross-sectional shape of a portion of the second emission layer contacting the partition wall may be different from each other.

In an embodiment, the first emission layer may include a first emission layer part on the first anode and having a top surface at a first height from a top surface of the base layer, and a second emission layer part on the pixel definition layer and having a top surface at a second height from the top surface of the base layer higher than the first height. The second height of the top surface of the second emission layer part may increase with decreasing distance from the partition wall.

In an embodiment, the second cathode may include a first cathode part on the second emission layer and having a top surface at a third height from a top surface of the base layer, and a second cathode part on the second emission layer and having a top surface at a fourth height from the top surface of the base layer higher than the third height. The fourth height of the top surface of the second cathode part may increase with decreasing distance from the partition wall.

In an embodiment, the first color may be a blue color.

In an embodiment, the display panel may further include a first encapsulation layer that includes a first encapsulation pattern covering the first emission opening and a second encapsulation pattern covering the second emission opening, and a second encapsulation layer that covers the first encapsulation layer.

In an embodiment, the display panel may further include a third emission element in a third emission opening of the plurality of emission openings, the third emission element including a third anode, a third emission layer on the third anode and including a light emitting material that generates light of a third color different from the first color, and a third cathode on the third emission layer and coupled to the partition wall. The second color may be one of green and red colors, and the third color may be another one of green and red colors.

In an embodiment, the second encapsulation pattern may further cover the third emission element.

In an embodiment, a cross-sectional shape of a portion of the second emission layer contacting the partition wall and a cross-sectional shape of a portion of the third emission layer contacting the partition wall may be substantially same.

According to an embodiment of the disclosure, a display panel may include a base layer, a pixel definition layer on the base layer and including a plurality of emission openings that are spaced apart from each other, a partition wall on the pixel definition layer and including a plurality of partition openings that overlap the plurality of emission openings in a plan view, the partition wall having conductivity, a first emission element in a first emission opening of the plurality of emission openings, the first emission element including a first anode, a first emission layer on the first anode and including a light emitting material that generates light of a first color, and a first cathode on the first emission layer and coupled to the partition wall, a second emission element in a second emission opening of the plurality of emission openings, the second emission element including a second anode, a second emission layer on the second anode and including a light emitting material that generates light of a second color different from the first color, and a second cathode on the second emission layer and coupled to the partition wall, a third emission element in a third emission opening of the plurality of emission openings, the third emission element including a third anode, a third emission layer on the third anode and including a light emitting material that generates light of a third color different from the first color, and a third cathode on the third emission layer and coupled to the partition wall, and a first encapsulation layer that includes a first encapsulation pattern covering the first emission opening and a second encapsulation pattern spaced apart from the first encapsulation pattern, the second encapsulation pattern covering the second and third emission openings.

In an embodiment, the display panel may further include a second encapsulation layer that covers the first encapsulation pattern and the second encapsulation pattern.

In an embodiment, a cross-sectional shape of a portion of the first emission layer contacting the partition wall and a cross-sectional shape of a portion of the second emission layer contacting the partition wall may be different from each other. The cross-sectional shape of the portion of the second emission layer the partition wall and a cross-sectional shape of a portion of the third emission layer contacting the partition wall may be substantially same.

In an embodiment, the first emission layer may include a first emission layer part on the first anode and having a top surface at a first height from a top surface of the base layer, and a second emission layer part on the pixel definition layer and having a top surface at a second height from the top surface of the base layer higher than the first height. The second height of the top surface of the second emission layer part may increase with decreasing distance from the partition wall.

According to an embodiment of the disclosure, a method of fabricating a display panel may include providing a preliminary display panel that includes a base layer, an anode on the base layer, and a preliminary pixel definition layer on the base layer and covering the anode, forming a partition wall having a plurality of partition openings on the preliminary pixel definition layer, forming a pixel definition layer by patterning the preliminary pixel definition layer to form a plurality of emission openings that correspondingly overlap the plurality of partition openings in a plan view and expose at least a portion of the anode; and forming a first emission layer and a first cathode in corresponding one of the plurality of partition openings, and forming a second emission layer and a second cathode in another corresponding one of the plurality of partition opening. The first emission layer may include a first light emitting material that generates light of a first color, the second emission layer may include a second light emitting material that generates light of a second color different from the first color, and the first and second cathodes may be in contact with the partition wall. The first emission layer may be formed by a thermal evaporation process. The second emission layer and the first emission layer may be formed by different processes.

In an embodiment, the second emission layer may be formed by an inkjet process.

In an embodiment, the first cathode may be formed by a deposition process. During the forming of the first emission layer and the first cathode, a deposition angle of the first emission layer and a deposition angle of the first cathode may be different from each other.

In an embodiment, the forming of the partition wall may include using a conductive material to from a first layer on the pixel definition layer, using a material to form a second layer on the first layer, the material being different from the conductive material, performing a first etching process in which the first layer and the second layer are patterned to form a first pattern, and performing a second etching process in which the first layer is under-cut with respect to the second layer. A lateral surface of the second layer may protrude from a lateral surface of the first layer and may form a tip.

In an embodiment, the plurality of emission openings may include a first emission opening and a second emission opening. The method may further include forming a first encapsulation pattern that covers the first emission opening, and forming a second encapsulation pattern that covers the second emission opening. The first encapsulation pattern and the second encapsulation pattern may be formed separated from each other.

In an embodiment, the first cathode and the second cathode may be formed separated from each other.

In an embodiment, the plurality of emission openings may include a first emission opening, a second emission opening, and a third emission opening. The method may further include forming in another corresponding one of the plurality of partition openings a third emission layer including a third light emitting material that generates light of a third color different from the first color and the second color; forming a third cathode separated from the first cathode, forming a first encapsulation pattern that covers the first emission opening, and forming a second encapsulation pattern that covers the second emission opening and the third emission opening and is separated from the first encapsulation pattern. The third emission layer and the first emission layer may be formed by different processes.

### BRIEF DESCRIPTION OF DRAWINGS

FIG. 1A illustrates a perspective view showing a display device according to an embodiment of the disclosure.

FIG. 1B illustrates an exploded perspective view showing a display device according to an embodiment of the disclosure.

FIG. 2 illustrates a schematic cross-sectional view showing a display module according to an embodiment of the disclosure.

FIG. 3 illustrates a plan view showing a display panel according to an embodiment of the disclosure.

FIG. 4 illustrates a schematic diagram of an equivalent circuit of a pixel according to an embodiment of the disclosure.

FIG. 5 illustrates an enlarged plan view partially showing a display panel according to an embodiment of the disclosure.

FIGS. 6A and 6B illustrate schematic cross-sectional views partially showing a display panel according to an embodiment of the disclosure.

FIGS. 7A and 7B illustrate schematic enlarged cross-sectional views partially showing a display panel according to an embodiment of the disclosure.

FIGS. 8A and 8B illustrate schematic enlarged cross-sectional views partially showing a display panel according to an embodiment of the disclosure.

FIGS. 9A to 9C illustrate schematic cross-sectional views partially showing a method of fabricating a display panel according to an embodiment of the disclosure.

FIGS. 10A to 10I illustrate schematic cross-sectional views partially showing a method of fabricating a display panel according to an embodiment of the disclosure.

FIGS. 11A to 11C illustrate schematic cross-sectional views partially showing a method of fabricating a display panel according to an embodiment of the disclosure.

### DETAILED DESCRIPTION OF EMBODIMENTS

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Like numerals indicate like components. Moreover, in the drawings, thicknesses, ratios, and dimensions of components are exaggerated for effectively explaining the technical contents. The term “and/or” includes one or more combinations defined by associated components.

It will be understood that, although the terms first, second, etc. may be used herein to describe various components, these components should not be limited by these terms. These terms are only used to distinguish one component from another component. For example, a first component could be termed a second component, and vice versa without departing from the scope of the disclosure. Unless the context clearly indicates otherwise, the singular forms are intended to include the plural forms as well.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

It should be understood that the terms “comprise”, “include”, “have”, and the like are used to specify the presence of stated features, integers, steps, operations, components, elements, or combinations thereof, but do not preclude the presence or addition of one or more other features, integers, steps, operations, components, elements, or combinations thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined, all terms used herein including technical and scientific terms have the same meaning generally understood by one of ordinary skilled in the art. Also, terms as defined in dictionaries generally used should be understood as having meaning identical or meaning contextually defined in the art and should not be understood as ideally or excessively formal meaning unless definitely defined herein.

With reference to the accompanying drawings, the following will describe a display panel and a method of fabricating the same according to an embodiment of the disclosure.

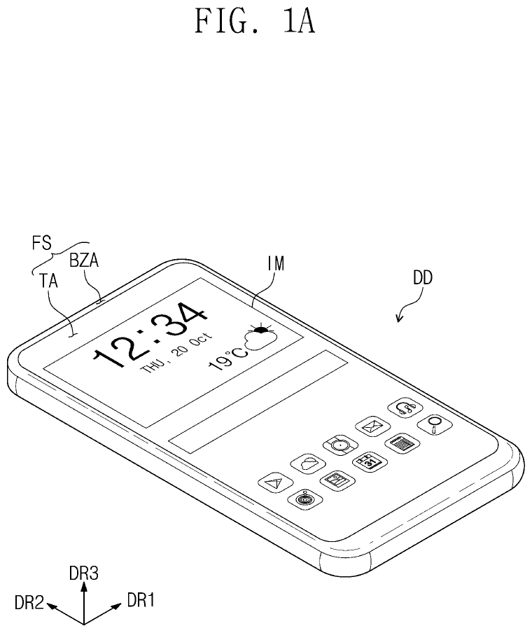

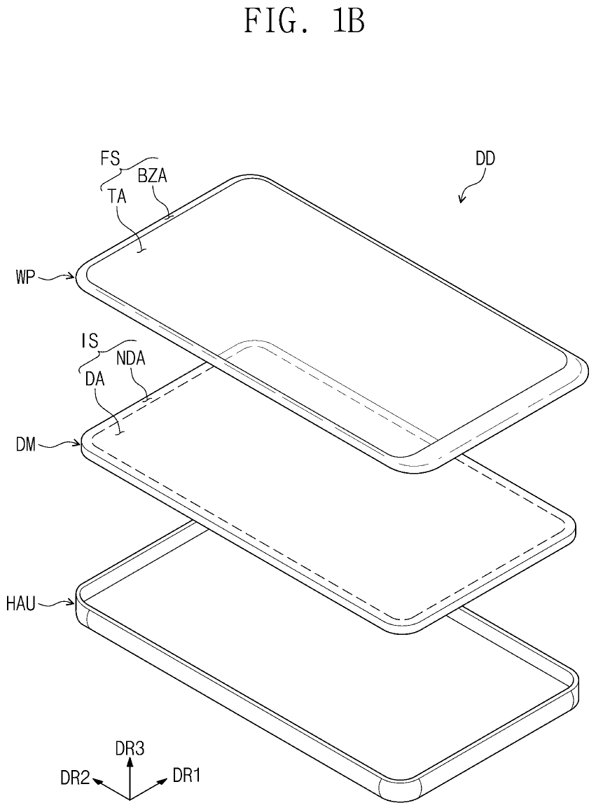

FIG. 1A illustrates a perspective view showing a display device according to an embodiment of the disclosure. FIG. 1B illustrates an exploded perspective view showing a display device according to an embodiment of the disclosure.

In an embodiment of the disclosure, a display device DD may be a large-sized electronic apparatus such as televisions, monitors, and outdoor billboards. In an embodiment, the display device DD may be a small and medium-sized electronic apparatus such as personal computers, laptop computers, personal digital terminals, automotive navigation units, game consoles, smart phones, tablet computers, and cameras. However, the disclosure is not limited thereto, and other display devices may be adopted as long as not deviated from the disclosure. FIGS. 1A and 1B depict a smart phone as an embodiment of the display device DD.

Referring to FIGS. 1A and 1B, the display device DD may display an image IM in a third direction DR3 on a display surface FS parallel to each of a first direction DR1 and a second direction DR2. The image IM may include not only dynamic images but also static images. FIG. 1A shows a clock window and icons as an example of the image IM. The display surface FS on which the image IM is displayed may correspond to a front surface of the display device DD.

In an embodiment, front and rear surfaces (or top and bottom surfaces) of each component may be defined based on a direction along which the image IM is displayed. The front and rear surfaces may be opposite to each other in the third direction DR3, and a normal direction to each of the front and rear surfaces may be parallel to the third direction DR3. Directions indicated by the first, second, and third directions DR1, DR2, and DR3 are relative concepts and may denote other directions. In this description, the phrase “when viewed in plane” or “in a plan view” may mean “when viewed in the third direction DR3.”

The display device DD may include a window WP, a display module DM, and a housing HAU. The window WP and the housing HAU may be combined with each other to constitute an appearance of the display device DD.

The window WP may include an optically transparent dielectric material. For example, the window WP may include glass or plastic. A front surface of the window WP may define the display surface FS of the display device DD. The display surface FS may include a transmission region TA and a bezel region BZA. The transmission region TA may be an optically transparent region. For example, the transmission region TA may be a region whose visible-light transmittance is equal to or greater than about 90%.

The bezel region BZA may be a region whose optical transmittance is relatively less than an optical transmittance of the transmission region TA. The bezel region BZA may define a shape of the transmission region TA. The bezel region BZA may be adjacent to and surround the transmission region TA. However, the disclosure is not limited thereto, and the bezel region BZA may be omitted from the window WP. The window WP may include at least one functional layer selected from an antifingerprint layer, a hard coating layer, and an antireflection layer, but the disclosure is not limited to a particular embodiment.

The display module DM may be disposed below the window WP. The display module DM may be a component that substantially generates the image IM. The image IM generated from the display module DM may be displayed on a display surface IS of the display module DM, and may be outwardly visible through the transmission region TA to users.

The display module DM may include a display region DA and a non-display region NDA. The display region DA may be a region activated with an electrical signal. The non-display region NDA may be adjacent to the display region DA. The non-display region NDA may surround the display region DA in a plan view. The non-display region NDA may be covered with the bezel region BZA, and may thus not be outwardly visible.

The housing HAU may be combined with the window WP. The housing HAU and the window WP may be combined with each other to provide an inner space. The display module DM may be accommodated in the inner space.

The housing HAU may include a material whose rigidity is relatively high. For example, the housing HAU may include at least one of glass, plastic, and metal, or may include multiple frames and/or plates each including any combination of glass, plastic, and metal. The housing HAU may stably protect, from external impact, components of the display device DD that are accommodated in the inner space.

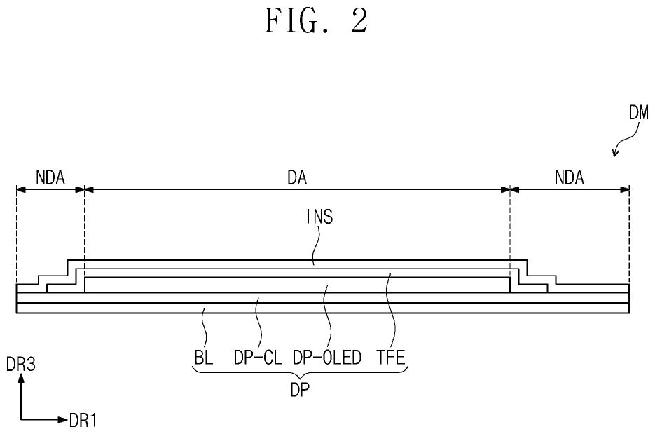

FIG. 2 illustrates a schematic cross-sectional view showing a display module according to an embodiment of the disclosure.

Referring to FIG. 2, the display module DM may include a display panel DP and an input sensor INS. Although not shown, the display device (see DD of FIG. 1A) according to an embodiment of the disclosure may further include either a protection member disposed on a bottom surface of the display panel DP or one or more of an antireflection member and a window member disposed on a top surface of the input sensor INS.

The display panel DP may be an emissive display panel. However, the disclosure is not particularly limited thereto. For example, the display panel DP may be an organic light emitting display panel or an inorganic light emitting display panel. An emission layer in the organic light emitting display panel may include an organic light emitting material. An emission layer in the inorganic light emitting display panel may include a quantum-dot, a quantum-rod, or a micro-LED. The following will describe an embodiment in which the display panel DP is an organic light emitting display panel.

The display panel DP may include a base layer BL and may also include a circuit element layer DP-CL, a display element layer DP-OLED, and a thin encapsulation layer TFE that are disposed on the base layer BL. The input sensor INS may be disposed (e.g., directly disposed) on the thin encapsulation layer TFE. In this description, the phrase “A component is directly disposed on B component” may mean that no adhesion layer is disposed between A component and B component.

The base layer BL may include at least one plastic film. The base layer BL may include a flexible substrate, for example, a plastic substrate, a glass substrate, a metal substrate, or an organic/inorganic composite substrate. The display region DA and the non-display region NDA discussed in FIG. 1B may be identically defined on the base layer BL.

The circuit element layer DP-CL may include at least one dielectric layer and a circuit element. The dielectric layer may include at least one inorganic layer and at least one organic layer. The circuit element may include a signal line, a pixel driver circuit, and the like.

The display element layer DP-OLED may include a partition wall and an emission element. The emission element may include an anode, an intermediate layer, and a cathode.

The thin encapsulation layer TFE may include multiple thin layers. A thin layer may be disposed for an increase in optical efficiency, and another thin layer may be provided for protection of organic light emitting diodes.

The input sensor INS may obtain coordinate information of external input. The input sensor INS may have a multi-layered structure. The input sensor INS may include a single conductive layer or multiple conductive layers. The input sensor INS may include a single dielectric layer or multiple dielectric layers. The input sensor INS may use a capacitance method to detect external inputs. However, the disclosure is not limited thereto. For example, in an embodiment, the input sensor INS may detect external inputs by using an electromagnetic induction method or a pressure sensing method. In another embodiment of the disclosure, the input sensor INS may be omitted.

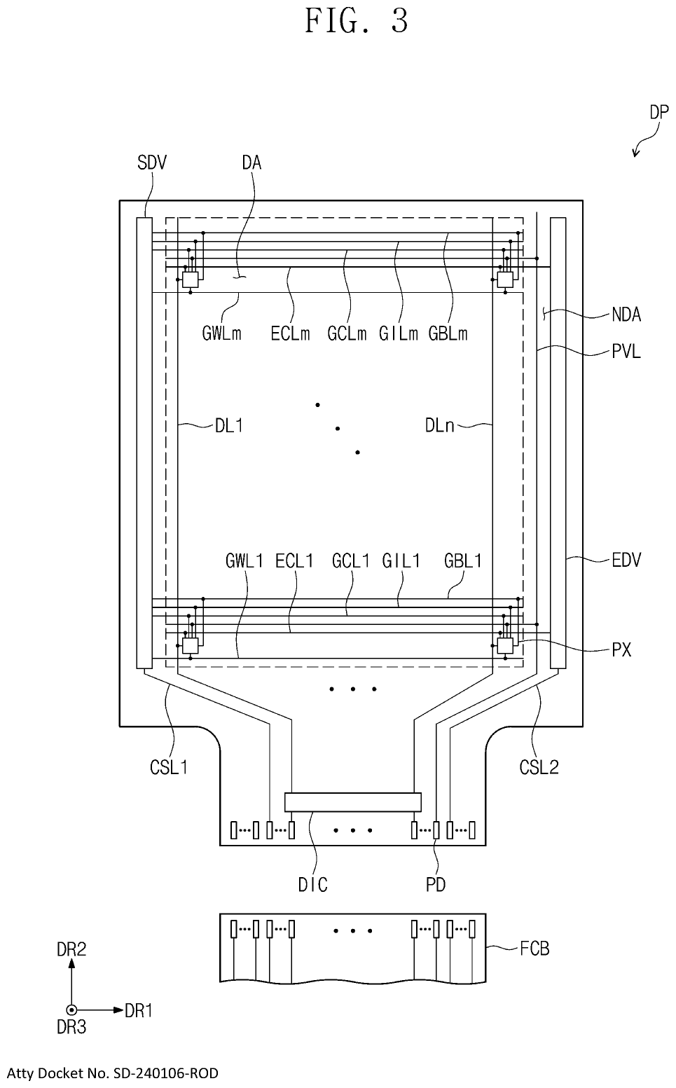

FIG. 3 illustrates a plan view showing a display panel according to an embodiment of the disclosure.

Referring to FIG. 3, the display panel DP may have a display region DA and a non-display region NDA adjacent to the display region DA. The display region DA and the non-display region NDA may be divided based on whether a pixel PX is disposed or not. The pixel PX may be disposed on the display region DA. A scan driver SDV, a data driver, and an emission driver EDV may be disposed in the non-display region NDA. The data driver may be a portion of circuits configured on a driver chip DIC.

The display panel DP may include pixels PX, initialization scan lines GIL1 to GILm, compensation scan lines GCL1 to GCLm, write scan lines GWL1 to GWLm, black scan lines GBL1 to GBLm, emission control lines ECL1 to ECLm, data lines DL1 to DLn, first and second control lines CSL1 and CSL2, a drive voltage line PVL, and multiple pads PD. The subscripts “m” and “n” are natural numbers.

The pixels PX may be connected to the initialization scan lines GIL1 to GILm, the compensation scan lines GCL1 to GCLm, the write scan lines GWL1 to GWLm, the black scan lines GBL1 to GBLm, the emission control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in the first direction DR1 and may be electrically connected to the scan driver SDV. The data lines DL1 to DLn may extend in the second direction DR2 and may be electrically connected to the driver chip DIC. The emission control lines ECL1 to ECLm may extend in the first direction DR1 and may be electrically connected to the emission driver EDV.

The drive voltage line PVL may include a part that extends in the first direction DR1 and a part that extends in the second direction DR2. The part extending in the first direction DR1 may be located at a different layer from the part extending in the second direction DR2. The drive voltage line PVL may provide the pixels PX with a drive voltage.

The first control line CSL1 may be connected to the scan driver SDV. The second control line CSL2 may be connected to the emission driver EDV.

The driver chip DIC, the drive voltage line PVL, the first control line CSL1, and the second control line CSL2 may be electrically connected to the pads PD. A flexible circuit film FCB may be electrically connected to the pads PD through an anisotropic conductive adhesion layer. The pads PD may connect the flexible circuit film FCB to the display panel DP. The pads PD may be connected to corresponding pixels PX through the drive voltage line PVL, the first control line CSL1, and the second control line CSL2.

The pads PD may further include input pads (not illustrated). The input pads may connect the flexible circuit film FCB to the input sensor (see INS of FIG. 2). The disclosure, however, is not limited thereto, and the input pads may be disposed on the input sensor INS and electrically connect the pads PD and a discrete circuit board. In another embodiment, the input sensor INS may be omitted, and no input pads may be included.

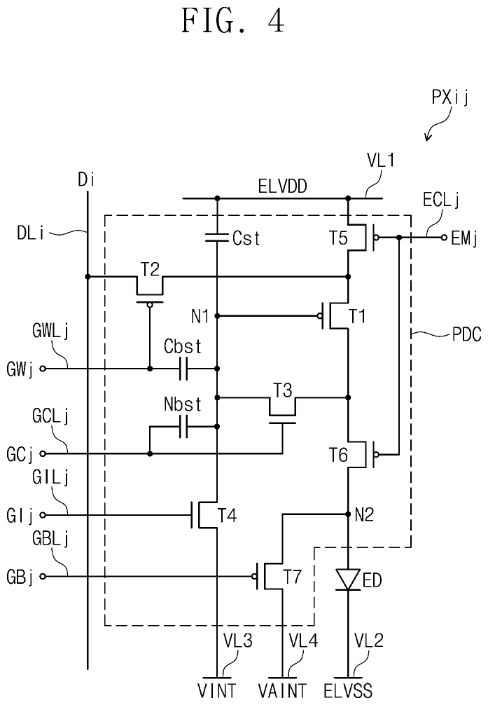

FIG. 4 illustrates a schematic diagram of an equivalent circuit of a pixel according to an embodiment of the disclosure.

FIG. 4 schematically illustrated an embodiment of an equivalent circuit diagram of one PXij among multiple pixels (see PX of FIG. 3). The pixels PX may have a same circuit structure, and thus the circuit structure of the pixel PXij will be discussed in detail below as an embodiment of the pixels PX.

Referring to FIGS. 3 and 4, the pixel PXij may be coupled to an i^{th} data line DLi of the data lines DL1 to DLn, a j^{th} initialization scan line GILj of the initialization scan lines GIL1 to GILm, a j^{th} compensation scan line GCLj of the compensation scan lines GCL1 to GCLm, a j^{th} write scan line GWLj of the write scan lines GWL1 to GWLm, a j^{th} black scan line GBLj of the black scan lines GBL1 to GBLm, a j^{th} emission control line ECLj of the emission control lines ECL1 to EMLm, first and second drive voltage lines VL1 and VL2, and first and second initialization voltage lines VL3 and VL4. i may be an integer between 1 and n, and j may be an integer between 1 and m.

The pixel PXij may include an emission element ED and a pixel circuit PDC. The emission element ED may be a light emitting diode. In an embodiment of the disclosure, the emission element ED may be an organic light emitting diode including an organic emission layer, but the disclosure is not particularly limited thereto. In response to a data signal Di, the pixel circuit PDC may control an amount of current that flows through the emission element ED. The emission element ED may emit light at a certain brightness level in response to an amount of current provided from the pixel circuit PDC.

The pixel circuit PDC may include first, second, third, fourth, fifth, sixth, and seventh transistors T1, T2, T3, T4, T5, T6, and T7 and first, second, and third capacitors Cst, Cbst, and Nbst. A configuration of the pixel circuit PDC according to the disclosure is not limited to the embodiment depicted in FIG. 4. The pixel circuit PDC depicted in FIG. 4 is an embodiment, and the configuration of the pixel circuit PDC may be variously changed.

At least one of the first to seventh transistors T1 to T7 may be a transistor having a low-temperature polycrystalline silicon (LTPS) semiconductor layer. At least one of the first to seventh transistors T1 to T7 may be a transistor having an oxide semiconductor layer. For example, the third and fourth transistors T3 and T4 may be oxide semiconductor transistors, and the first, second, fifth, sixth, and seventh transistors T1, T2, T5, T6, and T7 may be LTPS transistors.

For example, the first transistor T1 that directly affects brightness of the emission element ED may include a semiconductor layer formed of polycrystalline silicon having high reliability, which may result in achievement of a high-resolution display device. As an oxide semiconductor has a high carrier mobility and a low leakage current, there may be no large voltage drop even in case that a driving time is long. For example, a low-frequency operation may be possible because there is no large color change in image caused by voltage drop even in the low-frequency operation. Because an oxide semiconductor has an advantage of low leakage current as discussed above, an oxide semiconductor may be adopted to form at least one of the third transistor T3 and the fourth transistor T4 that are connected to a gate electrode of the first transistor T1, such that it may be possible not only to prevent a leakage current that can be introduced to the gate electrode but also to reduce a consumption power.

One or more of the first to seventh transistors T1 to T7 may be p-type transistors, and remaining one of the first to seventh transistors T1 to T7 may be n-type transistors. For example, the first, second, fifth, sixth, and seventh transistors T1, T2, T5, T6, and T7 may be p-type transistors, and the third and fourth transistors T3 and T4 may be n-type transistors.

The configuration of the pixel circuit PDC according to the disclosure is not limited to the embodiment depicted in FIG. 4. The pixel circuit PDC depicted in FIG. 4 is an embodiment, and the configuration of the pixel circuit PDC may be variously changed. For example, all of the first to seventh transistors T1 to T7 may be p-type transistors or n-type transistors. For example, the first, second, fifth, and sixth transistors T1, T2, T5, and T6 may be p-type transistors, and the third, fourth, and seventh transistors T3, T4, and T7 may be n-type transistors.

The j^{th} initialization scan line GILj, the j^{th} compensation scan line GCLj, the j^{th} write scan line GWLj, the j^{th} black scan line GBLj, and the j^{th} emission control line ECLj may provide the pixel PXij with a j^{th} initialization scan signal GIj, a j^{th} compensation scan signal GCj, a j^{th} write scan signal GWj, a j^{th} black scan signal GBj, and a j^{th} emission control signal EMj, respectively. The i^{th} data line DLi may transmit an i^{th} data signal Di to the pixel PXij. The i^{th} data signal Di may have a voltage level that corresponds to the image signal that is input to the display device (see DD of FIG. 1).

A first drive voltage ELVDD and a second drive voltage ELVSS may be transmitted to the pixel PXij through the first drive voltage line VL1 and the second drive voltage line VL2, respectively. A first initialization voltage VINT and a second initialization voltage VAINT may be transmitted to the pixel PXij through the first initialization voltage line VL3 and the second initialization voltage line VL4, respectively.

The first transistor T1 may be coupled between the emission element ED and the first drive voltage line VL1 to which the first drive voltage ELVDD is applied. The first transistor T1 may include a first electrode that is connected through the fifth transistor T5 to the first drive voltage line VL1, a second electrode that is connected through the sixth transistor T6 to a pixel electrode (or an anode) of the emission element ED, and a third electrode (e.g., a gate electrode) that is connected to an end (e.g., a first node N1) of the first capacitor Cst. The first transistor T1 may supply the emission element ED with a drive current by receiving the i^{th} data signal Di that is transmitted through the i^{th} data line DLi in accordance with a switching operation of the second transistor T2.

The second transistor T2 may be coupled between the i^{th} data line DLi and the first electrode of the first transistor T1. The second transistor T2 may include a first electrode connected to the i^{th} data line DLi, a second electrode connected to the first electrode of the first transistor T1, and a third electrode (e.g., a gate electrode) connected to the j^{th} write scan line GWLj. The second transistor T2 may be turned on by the j^{th} write scan signal GWj transmitted through the j^{th} write scan line GWLj, and may provide the first electrode of the first transistor T1 with the i^{th} data signal Di transmitted from the i^{th} data line DLi. An end of the second capacitor Cbst may be connected to the third electrode of the second transistor T2, and another end of the second capacitor Cbst may be connected to the first node N1.

The third transistor T3 may be coupled between the first node N1 and the second electrode of the first transistor T1. The third transistor T3 may include a first electrode connected to the third electrode of the first transistor T1, a second electrode connected to the second electrode of the first transistor T1, and a third electrode (e.g., a gate electrode) connected to the j^{th} compensation scan line GCLj. The third transistor T3 may be turned on by the j^{th} compensation scan signal GCj transmitted through the j^{th} compensation scan line GCLj, and may connect the third and second electrodes of the first transistor T1 to each other to thereby diode-connect the first transistor T1. An end of the third capacitor Nbst may be connected to the third electrode of the third transistor T3, and another end of the third capacitor Nbst may be connected to the first node N1.

The fourth transistor T4 may be coupled between the first node N1 and the first initialization voltage line VL3 to which the first initialization voltage VINT is applied. The fourth transistor T4 may include a first electrode connected to the first initialization voltage line VL3 through which the first initialization voltage VINT is transmitted, a second electrode connected to the first node N1, and a third electrode (e.g., a gate electrode) connected to the j^{th} initialization scan line GILj. The fourth transistor T4 may be turned on by the j^{th} initialization scan signal GIj transmitted through the j^{th} initialization scan line GILj. The turned-on fourth transistor T4 may provide the first node N1 with the first initialization voltage VINT to initialize a potential of the third electrode of the first transistor T1 (or a potential of the first node N1).

The fifth transistor T5 may include a first electrode connected to first drive voltage line VL1, a second electrode connected to the first electrode of the first transistor T1, and a third electrode (e.g., a gate electrode) connected to the j^{th} emission control line ECLj. The sixth transistor T6 may include a first electrode connected to the second electrode of the first transistor T1, a second electrode connected to the pixel electrode of the emission element ED, and a third electrode (e.g., a gate electrode) connected to the j^{th} emission control line ECLj.

The fifth and sixth transistors T5 and T6 may be simultaneously turned on by the j^{th} emission control signal EMj transmitted through the j^{th} emission control line ECLj. The first drive voltage ELVDD applied through the turned-on fifth transistor T5 may be compensated by the diode-connected first transistor T1 and may be transmitted through the sixth transistor T6 to the emission element ED.

The seventh transistor T7 may include a first electrode connected to the second initialization voltage line VL4 through which the second initialization voltage VAINT is transmitted, a second electrode connected to the second electrode of the sixth transistor T6, and a third electrode (e.g., a gate electrode) connected to the j^{th} black scan line GBLj. The second initialization voltage VAINT may have a voltage level the same as or less than a voltage level of the first initialization voltage VINT.

An end of the first capacitor Cst may be connected to the third electrode of the first transistor T1, and another end of the first capacitor Cst may be connected to the first drive voltage line VL1. A cathode of the emission element ED may be connected to the second drive voltage line VL2 through which the second drive voltage ELVSS is transmitted. The second drive voltage ELVSS may have a voltage level less than a voltage level of the first drive voltage ELVDD.

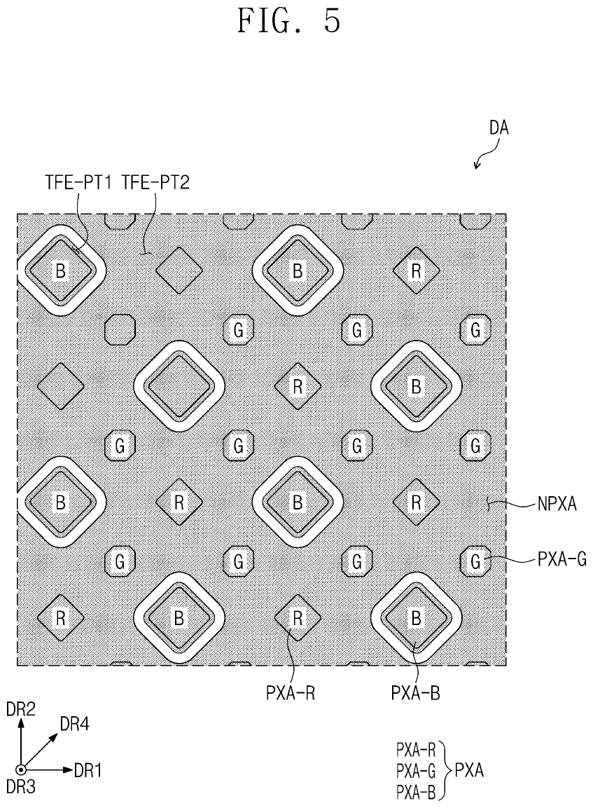

FIG. 5 illustrates an enlarged plan view partially showing a display region of a display panel according to an embodiment of the disclosure. FIG. 5 depicts a plane of a display module when viewed on a display surface of the display module, and shows an arrangement of emission regions.

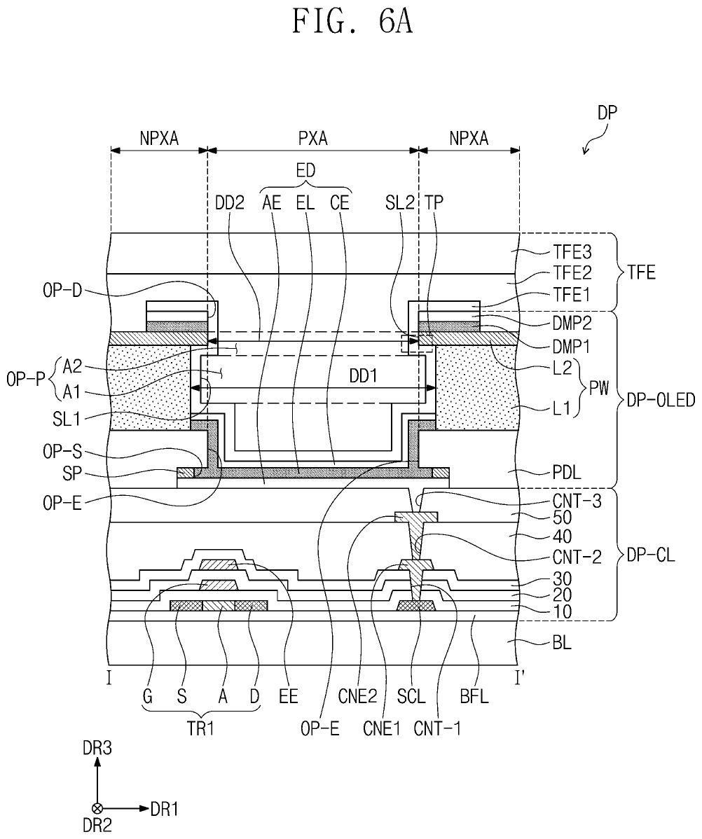

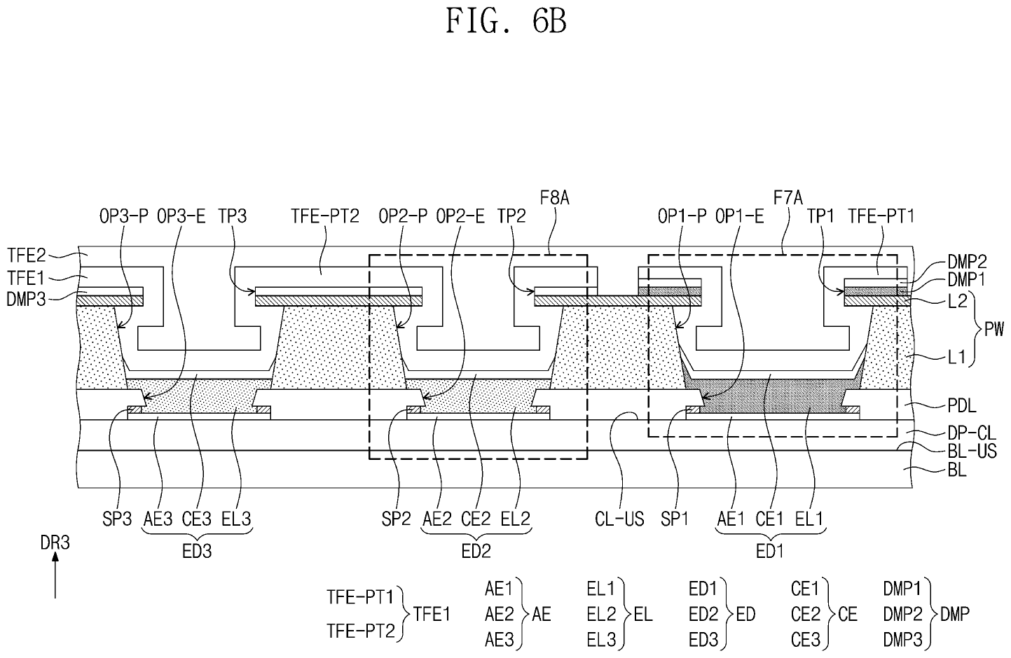

Referring to FIG. 5, the display region DA may include an emission region PXA including first, second, and third emission regions PXA-B, PXA-G, and PXA-R and a peripheral region NPXA that surrounds the first, second, and third emission regions PXA-B, PXA-G, and PXA-R in a plan view. The first, second, and third emission regions PXA-B, PXA-G, and PXA-R may correspond to regions that emit light rays provided from respective emission elements (see ED1, ED2, and ED3 of FIG. 6B). The first, second, and third emission regions PXA-B, PXA-G, and PXA-R may be distinguished from each other based on a color of light that is outwardly emitted from the display module (see DM of FIG. 2).

The first, second, and third emission regions PXA-B, PXA-G, and PXA-R may provide light rays having first to third colors different from each other. For example, the first color light may be blue light, the second color light may be green light, and the third color light may be red light. However, the first color light, the second color light, and the third color light are not necessarily limited to the embodiment mentioned above.

Each of the first, second, and third emission regions PXA-B, PXA-G, and PXA-R may be defined to indicate a zone where a top surface of an anode is exposed by an emission opening which will be discussed below. The peripheral region NPXA may establish boundaries of the first, second, and third emission regions PXA-B, PXA-G, and PXA-R, and may prevent a color mixing between the first, second, and third emission regions PXA-B, PXA-G, and PXA-R.

Each of the first, second, and third emission regions PXA-B, PXA-G, and PXA-R may be provided in plural, and in the display region DA, the first, second, and third emission regions PXA-B, PXA-G, and PXA-R may be repeatedly arranged with a pattern. For example, the first and third emission regions PXA-B and PXA-R may be alternately arranged in the first direction DR1 to constitute a first group. The second emission regions PXA-G may be arranged in the first direction DR1 to constitute a second group. Each of the first group and the second group may be provided in plural, and the first groups and the second groups may be alternately arranged in the second direction DR2.

A second emission region PXA-G may be disposed spaced apart in a fourth direction DR4 from a first emission region PXA-B or a third emission region PXA-R. The fourth direction DR4 may be a direction between the first and second directions DR1 and DR2.

FIG. 5 depicts an arrangement of the first, second, and third emission regions PXA-B, PXA-G, and PXA-R according to an embodiment, but the disclosure is not limited thereto. In an embodiment, the first, second, and third emission regions PXA-B, PXA-G, and PXA-R may be arranged in a PenTile™ pattern as shown in FIG. 5. In another embodiment, the first, second, and third emission regions PXA-B, PXA-G, and PXA-R may be arranged in a stripe pattern or Diamond Pixel™ pattern.

The first, second, and third emission regions PXA-B, PXA-G, and PXA-R may have various shapes in a plan view. For example, the first, second, and third emission regions PXA-B, PXA-G, and PXA-R may have a polygonal shape, a circular shape, or an oval shape. FIG. 5 depicts an embodiment that, in a plan view, the first and third emission regions PXA-B and PXA-R have a tetragonal or rhombic shape, and the second emission region PXA-G has an octagonal shape.

In a plan view, the first, second, and third emission regions PXA-B, PXA-G, and PXA-R may have a same shape as each other, or one or more of the first, second, and third emission regions PXA-B, PXA-G, and PXA-R may have different shapes from each other. FIG. 5 shows an embodiment that, in a plan view, the first and third emission regions PXA-B and PXA-R have a same shape as each other, and the second emission region PXA-G has a different shape from a shape of the first and third emission regions PXA-B and PXA-R.

One or more of the first, second, and third emission regions PXA-B, PXA-G, and PXA-R may have different areas from each other in a plan view. In an embodiment, the area of the first emission region PXA-B from which the blue light is emitted may be greater than the area of the second emission region PXA-G from which the green light is emitted and less than the area of the third emission region PXA-R from which the red light is emitted. The area size inequality between the first, second, and third emission regions PXA-B, PXA-G, and PXA-R in accordance with the color of light is not limited thereto, and may be variously changed depending on design of the display module (see DM of FIG. 2). The disclosure is not limited thereto, and the first, second, and third emission regions PXA-B, PXA-G, and PXA-R may have a same area in a plan view.

According to an embodiment of the disclosure, the display panel (see DP of FIG. 2) may include a first encapsulation pattern TFE-PT1 and a second encapsulation pattern TFE-PT2 that cover the first, second, and third emission regions PXA-B, PXA-G, and PXA-R.

The first encapsulation pattern TFE-PT1 and the second encapsulation pattern TFE-PT2 may be spaced apart from each other in a plan view. The first encapsulation pattern TFE-PT1 may cover a first emission opening (see OP1-E of FIG. 6B) where a first emission layer (see EL1 of FIG. 6B) is disposed. The second encapsulation pattern TFE-PT2 may cover a second emission opening (see OP2-E of FIG. 6B) where a second emission layer (see EL2 of FIG. 6B) is disposed and a third emission opening (see OP3-E of FIG. 6B) where a third emission layer (see EL3 of FIG. 6B) is disposed. The first encapsulation pattern TFE-PT1 may not overlap any of the second emission region PXA-G and the third emission region PXA-R in a plan view, and the second encapsulation pattern TFE-PT2 may not overlap the first emission region PXA-B in a plan view.

As discussed below, the first encapsulation pattern TFE-PT1 and the second encapsulation pattern TFE-PT2 may be formed in different process steps and spaced apart from each other. The first encapsulation pattern TFE-PT1 and the second encapsulation pattern TFE-PT2 may be formed in a same process step and spaced apart from each other, but the disclosure is not limited to one specific embodiment.

A shape, area, and arrangement of the first, second, and third emission regions PXA-B, PXA-G, and PXA-R of the display module (see DM of FIG. 2) according to the disclosure may be variously designed in accordance with a color of emitted light, a size of the display module (see DM of FIG. 2), and/or a configuration of the display module DM, but the disclosure is not limited to the embodiment depicted in FIG. 5.

FIGS. 6A and 6B illustrate schematic cross-sectional views partially showing a display panel according to an embodiment of the disclosure. FIG. 6A depicts an enlarged cross-sectional view showing one emission region PXA in the display region (see DA of FIG. 5). FIG. 6B depicts an enlarged cross-sectional view showing one first emission region PXA-B, one second emission region PXA-G, and one third emission region PXA-R. In the explanation of FIGS. 6A and 6B, FIG. 5 will be used, and omission will be made to avoid a duplicate description of components allocated the same reference symbols.

Referring to FIGS. 6A and 6B, the display panel DP may include a base layer BL, a circuit element layer DP-CL, a display element layer DP-OLED, and an encapsulation layer TFE.

The display panel DP may include multiple dielectric layers, a semiconductor pattern, a conductive pattern, and a signal line. A dielectric layer, a semiconductor layer, and a conductive layer may be formed by coating and deposition. After coating or deposition, the dielectric layer, the semiconductor layer, and the conductive layer may be selectively patterned by photolithography and etching. The processes mentioned above may form the semiconductor pattern, the conductive pattern, and the signal line that are included in the circuit element layer DP-CL and the display element layer DP-OLED.

The circuit element layer DP-CL may be disposed on the base layer BL. The circuit element layer DP-CL may include a buffer layer BFL, a transistor TR1, a signal delivery section SCL, first to fifth dielectric layers 10, 20, 30, 40, and 50, an electrode EE, and multiple connection electrodes CNE1 and CNE2.

The buffer layer BFL may be disposed on the base layer BL. The buffer layer BFL may increase a bonding force between the base layer BL and the semiconductor pattern. The buffer layer BFL may include a silicon oxide layer and a silicon nitride layer. The silicon oxide layer and the silicon nitride layer may be alternately stacked each other.

A semiconductor pattern may be disposed on the buffer layer BFL. The semiconductor pattern may include polysilicon. The disclosure, however, is not limited thereto, and the semiconductor pattern may include amorphous silicon or a metal oxide. FIG. 6A depicts a portion of the semiconductor pattern, and in an embodiment, the semiconductor pattern may further be disposed on multiple emission regions (see PXA-R, PXA-G, and PXA-B of FIG. 5). The semiconductor pattern may be disposed at a specific rule across the emission regions (see PXA-R, PXA-G, and PXA-B of FIG. 5). The semiconductor pattern may have different electrical properties based on whether the semiconductor pattern is doped or not. The semiconductor pattern may include a first section whose doping concentration is high and a second section whose doping concentration is low. The first section may be doped with n-type or p-type impurities. A p-type transistor may include the first section doped with p-type impurities.

The first section may have conductivity greater than a conductivity of the second section, and may substantially serve as an electrode or a signal line. The second section may substantially correspond to an active (or channel) of a transistor. For example, a portion of the semiconductor pattern may be an active of a transistor, and another portion of the semiconductor pattern may be a source or drain of a transistor, and still another portion of the semiconductor pattern may be a conductive region.

The semiconductor pattern may be formed into a source S, an active A, and a drain D of the transistor TR1. FIG. 6A depicts a portion of the signal delivery section SCL formed from the semiconductor pattern. Although not shown, the signal delivery section SCL may be connected to the drain D of the transistor TR1.

The first to fifth dielectric layers 10 to 50 may be disposed on the buffer layer BFL. The first to fifth dielectric layers 10 to 50 may be an inorganic layer or an organic layer.

The first dielectric layer 10 may be disposed on the buffer layer BFL. A gate G may be disposed on the first dielectric layer 10. The second dielectric layer 20 may be provided on the first dielectric layer 10 and cover the gate G. The electrode EE may be disposed on the second dielectric layer 20. The third dielectric layer 30 may be provided on the second dielectric layer 20 and cover the electrode EE.

A first connection electrode CNE1 may be disposed on the third dielectric layer 30. The first connection electrode CNE1 may be coupled to the signal delivery section SCL through a contact hole CNT-1 that penetrates the first, second, and third dielectric layers 10, 20, and 30. The fourth dielectric layer 40 may be provided on the third dielectric layer 30 and cover the first connection electrode CNE1. The fourth dielectric layer 40 may be an organic layer.

A second connection electrode CNE2 may be disposed on the fourth dielectric layer 40. The second connection electrode CNE2 may be coupled to the first connection electrode CNE1 through a contact hole CNT-2 that penetrates the fourth dielectric layer 40. The fifth dielectric layer 50 may be provided on the fourth dielectric layer 40 and cover the second connection electrode CNE2. The fifth dielectric layer 50 may be an organic layer.

The display element layer DP-OLED may be disposed on the circuit element layer DP-CL. The display element layer DP-OLED may include an emission element ED, a pixel definition layer PDL, a partition wall PW, and a dummy pattern DMP.

In the disclosure, the emission element ED may include an anode AE (or a first electrode), a conductive pattern, an emission layer EL, and a cathode CE (or a second electrode).

The anode AE may be disposed on the fifth dielectric layer 50 of the circuit element layer DP-CL. The anode AE may be a transmissive electrode, a transflective electrode, or a reflective electrode. The anode AE may have conductivity. For example, the anode AE may be formed of various materials, such as a metal, a transparent conductive oxide (TCO), or a conductive polymer, as long as the materials have conductivity. The anode AE may be configured as single-layered or multi-layered. In an embodiment, the anode AE may be configured three-layered including indium tin oxide (ITO), silver (Ag), and indium tin oxide (ITO).

The anode AE may be coupled to the second connection electrode CNE2 through a coupling contact hole CNT-3 defined to penetrate the fifth dielectric layer 50. Therefore, the anode AE may be electrically connected to the signal delivery section SCL through the first and second connection electrodes CNE1 and CNE2 and electrically connected to a corresponding circuit element.

According to an embodiment of the disclosure, the display panel DP may further include sacrificial patterns SP1, SP2, and SP3. The sacrificial patterns SP1, SP2, and SP3 may each be disposed on a top surface of the anode AE. The sacrificial patterns SP1, SP2, and SP3 may each have a sacrificial opening that is defined to expose a portion of the top surface of the anode AE. The sacrificial patterns SP1, SP2, and SP3 may include an amorphous transparent conductive oxide.

The pixel definition layer PDL may be disposed on the fifth dielectric layer 50 of the circuit element layer DP-CL. The pixel definition layer PDL may include multiple emission openings OP1-E, OP2-E, and OP3-E. Each of the emission openings OP1-E, OP2-E, and OP3-E may overlap the anode AE in a plan view, and the pixel definition layer PDL may expose at least a portion of the anode AE through the emission openings OP1-E, OP2-E, and OP3-E.

The emission openings OP1-E, OP2-E, and OP3-E may overlap the sacrificial openings of the sacrificial patterns SP1, SP2, and SP3 in a plan view. According to the disclosure, in a cross-sectional view, the top surface of the anode AE may be spaced apart from the pixel definition layer PDL across the sacrificial patterns SP1, SP2, and SP3, and thus the anode AE may be protected against damage in a process for forming the emission openings OP1-E, OP2-E, and OP3-E.

Each of the emission openings OP1-E, OP2-E, and OP3-E may have a width in a direction less than a width in the direction of the sacrificial opening. In this description, the direction may indicate a direction perpendicular to a thickness direction (e.g., the third direction DR3) of the display panel DP. The pixel definition layer PDL may have inner lateral surfaces that define the emission openings OP1-E, OP2-E, and OP3-E, and the inner lateral surfaces of the pixel definition layer PDL may be closer to a center of the anode AE than inner lateral surfaces of the sacrificial patterns SP1, SP2, and SP3. The disclosure, however, is not limited thereto, and the inner lateral surfaces of the sacrificial patterns SP1, SP2, and SP3 that define the sacrificial openings may be substantially aligned with the inner lateral surfaces of the pixel definition layer PDL that define the emission openings OP1-E, OP2-E, and OP3-E. The emission region PXA may correspond to an area of the anode AE exposed from a corresponding sacrificial opening. In an embodiment of the disclosure, the sacrificial patterns SP1, SP2, and SP3 may be omitted.

The pixel definition layer PDL may include an inorganic dielectric material. For example, the pixel definition layer PDL may include silicon nitride (SiNₓ). The pixel definition layer PDL may be disposed between the anode AE and the partition wall PW to prevent an electrical connection between the anode AE and the partition wall PW.

The partition wall PW may be disposed on the pixel definition layer PDL. The partition wall PW may include multiple partition openings OP1-P, OP2-P, and OP3-P. The partition openings OP1-P, OP2-P, and OP3-P may correspond to the emission openings OP1-E, OP2-E, and OP3-E, and may expose at least a portion of the anode AE.

The partition wall PW may have an undercut shape in a cross-sectional view. The partition wall PW may include multiple layers that are sequentially stacked, and at least one of the layers may be more recessed than adjacently stacked layers. Therefore, the partition wall PW may include multiple tips TP1, TP2, and TP3.

In an embodiment, the partition wall PW may include a first partition layer L1 and a second partition layer L2. The first partition layer L1 may be disposed on the pixel definition layer PDL, and the second partition layer L2 may be disposed on the first partition layer L1. As shown in FIG. 6A, a thickness of the first partition layer L1 may be greater than a thickness of the second partition layer L2, but the disclosure is not limited thereto. The partition wall PW is illustrated to include only the first partition layer L1 and the second partition layer L2 in FIG. 6B, but the disclosure is not limited thereto, and in another embodiment, a third partition layer may be disposed but not limited to on the second partition layer L2. A thickness of the third partition wall may be greater than a thickness of the second partition layer L2, but the disclosure is not limited thereto.

The first partition layer L1 may have conductivity. The first partition layer L1 may include a conductive material. For example, the first partition layer L1 may include a metal, a metal nitride, a transparent conductive oxide (TCO), or a combination thereof. For example, the first partition layer L1 may include a metal such as gold (Au), silver (Sg), aluminum (Al), magnesium (Mg), lithium (Li), molybdenum (Mo), titanium (Ti), copper (Cu), or an alloy thereof. The first partition layer L1 may include a metal nitride such as titanium nitride (TiN). The first partition Layer L1 may include a transparent conductive oxide such as indium tin oxide (ITO), indium zinc oxide (IZO), zinc oxide (ZnO), indium oxide (InO), indium gallium oxide (IGO), indium gallium zinc oxide (IGZO), or aluminum zinc oxide (AZO).

The second partition layer L2 may be disposed on the first partition layer L1. The second partition layer L2 may include a material having an etch selectivity with respect to the first partition layer L1. For example, the second partition layer L2 may have reactivity less than a reactivity of the first partition layer L1.

In an embodiment, compared to the second partition layer L2, the first partition layer L1 may be relatively recessed with respect to the emission region PXA. For example, the first partition layer L1 may be formed by undercutting the second partition layer L2. The second partition layer L2 may have portions that protrude from the first partition layer L1 toward the emission region PXA, and the protruding portions of the second partition layer L2 may be defined as the tips TP1, TP2, and TP3 of the partition wall PW.

The second partition layer L2 may include a conductive material. For example, the second partition layer L2 may include a metal, a metal nitride, a transparent conductive oxide (TCO), or a combination thereof. For example, the second partition layer L2 may include a metal such as gold (Au), silver (Sg), aluminum (Al), magnesium (Mg), lithium (Li), molybdenum (Mo), titanium (Ti), copper (Cu), or an alloy thereof. The second partition layer L2 may include a metal nitride such as titanium nitride (TiN). The second partition layer L2 may include a transparent conductive oxide such as indium tin oxide (ITO), indium zinc oxide (IZO), zinc oxide (ZnO), indium oxide (InO), indium gallium oxide (IGO), indium gallium zinc oxide (IGZO), or aluminum zinc oxide (AZO).

In another embodiment of the disclosure, the second partition layer L2 may include a dielectric material. For example, the second partition layer L2 may include an inorganic dielectric material, such as silicon nitride (SiNₓ) or silicon oxide (SiOₓ). However, the disclosure is not limited thereto, and in the partition wall PW according to an embodiment of the disclosure, the second partition layer L2 may be omitted.

In an embodiment, a second inner lateral surface of the second partition layer L2 may be closer to a center of the anode AE than a first inner lateral surface of the first partition layer L1. For example, compared to the second inner lateral surface of the second partition layer L2, the first inner lateral surface of the first partition layer L1 may be disposed as being recessed in a direction departing from the center of the anode AE. Thus, the second partition layer L2 may have a bottom surface exposed from the first partition layer L1.

The partition wall PW may have an undercut shape in a cross-sectional view. As discussed above, the undercut shape of the partition wall PW may be defined by a step difference between the first inner lateral surface of the first partition layer L1 and the second inner lateral surface of the second partition layer L2. However, the cross-sectional shape of the partition wall PW is not limited thereto, and the partition wall PW may have but not limited to an inverse tapered shape, an overhang shape, or any other suitable shapes.

FIG. 6A depicts that each of the first inner lateral surface of the first partition layer L1 and the second inner lateral surface of the second partition layer L2 is perpendicular to a top surface of the fifth dielectric layer 50, but the disclosure is not limited thereto. In another embodiment, as illustrated in FIG. 6B, each of the first inner lateral surface of the first partition layer L1 and the second inner lateral surface of the second partition layer L2 is inclined to the top surface of the fifth dielectric layer 50.

The emission layer EL may be disposed on the anode AE. The emission layer EL may be patterned by the tips TP1, TP2, and TP3 defined in the partition wall PW. At least a portion of the emission layer EL may be disposed in the emission openings OP1-E, OP2-E, and OP3-E. The emission layer EL may all be disposed in the emission openings OP1-E, OP2-E, and OP3-E, or may be disposed not only in the emission openings OP1-E, OP2-E, and OP3-E but also in the partition openings OP1-P, OP2-P, and OP3-P. In an embodiment including the sacrificial patterns SP1, SP2, and SP3, the emission layer EL may also be disposed in the sacrificial opening.

The emission layer EL may include a light emitting material. A hole injection layer (HIL) and a hole transport layer (HTL) may be disposed between the emission layer EL and the anode AE. An electron transport layer (ETL) and an electron injection layer (EIL) may be disposed on the emission layer EL.

Referring to FIG. 6B, the emission layer EL may include a first emission layer EL1, a second emission layer EL2, and a third emission layer EL3. The first emission layer EL1 may be disposed in a first partition opening OP1-P, the second emission layer EL2 may be disposed in a second partition opening OP2-P, and the third emission layer EL3 may be disposed in a third partition opening OP3-P.

The first emission layer EL1 may include a first light emitting material that produces light of a first color, the second emission layer EL2 may include a second light emitting material that produces light of a second color, and the third emission layer EL3 may include a third light emitting material that produces light of a third color. For example, the first color may be a blue color, the second color may be one of green and red colors, and the third color may be another one of green and red colors.

According to an embodiment of the disclosure, a contact area between the first emission layer EL1 and the partition wall PW may be different from a contact area between the second emission layer EL2 and the partition wall PW. The contact area between the second emission layer EL2 and the partition wall PW and the contact area between the third emission layer EL3 and the partition wall PW may be substantially the same.

A contact portion of the first emission layer EL1 with the partition wall PW may have a cross-sectional shape different from a cross-sectional shape of a contact portion of the second emission layer EL2 with the partition wall PW. The cross-sectional shape of the contact portion of the first emission layer EL1 with the partition wall PW and a cross-sectional shape of a contact portion of the third emission layer EL3 with the partition wall PW may be substantially the same.

The cathode CE may be disposed on the emission layer EL. The emission layer EL may be patterned by the tips TP1, TP2, and TP3 defined in the partition wall PW. At least a portion of the cathode CE may be disposed in the partition openings OP1-P, OP2-P, and OP3-P. In an embodiment of the disclosure, in accordance with a thickness of the emission layer EL or a thickness of the pixel definition layer PDL, a portion of the cathode CE may also be disposed in the emission openings OP1-E, OP2-E, and OP3-E.

The cathode CE may have conductivity. For example, the cathode CE may be formed of various materials, such as a metal, a transparent conductive oxide (TCO), or a conductive polymer, as long as the materials have conductivity.

The cathode CE may include a first cathode CE1, a second cathode CE2, and a third cathode CE3. The first cathode CE1 may be disposed in the first partition opening OP1-P, the second cathode CE2 may be disposed in the second partition opening OP2-P, and the third cathode CE3 may be disposed in the third partition opening OP3-P.

Referring again to FIG. 6B, a contact area between the first cathode CE1 and the partition wall PW, a contact area between the second cathode CE2 and the partition wall PW, and a contact area between the third cathode CE3 and the partition wall PW may be substantially the same. As substantially the same area is provided between the partition wall PW and each of the first, second, and third cathodes CE1, CE2, and CE3, it may be possible to secure reliability of electrical connection and readily deliver signal.

A cross-sectional shape of the first cathode CE1 may be different from a cross-sectional shape of the second cathode CE2. The second cathode CE2 and the third cathode CE3 may have substantially the same cross-sectional shape, but the disclosure is not limited to a specific embodiment.

According to an embodiment of the disclosure, the display panel DP may further include a capping pattern. The capping pattern may be disposed on the cathode CE. The capping pattern may be patterned by the tips TP1, TP2, and TP3 defined in the partition wall PW. At least a portion of the capping pattern may be disposed in the partition openings OP1-P, OP2-P, and OP3-P.

The dummy patterns DMP may be disposed on the partition wall PW. The dummy pattern DMP may include a first dummy pattern DMP1, a second dummy pattern DMP2, and a third dummy pattern DMP3.

The first dummy pattern DMP1 may include an organic material. For example, the first dummy pattern DMP1 and the first emission layer EL1 may include a same material. The first dummy pattern DMP1 and the first emission layer EL1 may be simultaneously formed in a process, and the undercut shape of the partition wall PW may cause the first dummy pattern DMP1 to form separately from the first emission layer EL1.

The second dummy pattern DMP2 may include a conductive material. For example, the second dummy pattern DMP2 and the first cathode CE1 may include a same material. The second dummy pattern DMP2 and the first cathode CE1 may be simultaneously formed in a process, and the undercut shape of the partition wall PW may cause the second dummy pattern DMP2 to form separately from the first cathode CE1.

The third dummy pattern DMP3 may include a conductive material. For example, the third dummy pattern DMP3 and the second cathode CE2 and/or that of the third cathode CE3 may include a same material. The third dummy pattern DMP3 and the second cathode CE2 (and/or the third cathode CE3) may be simultaneously formed in a process, and the undercut shape of the partition wall PW may cause the third dummy pattern DMP3 to form separately from the second cathode CE2 (and/or the third cathode CE3).

The encapsulation layer TFE may be disposed on the display element layer DP-OLED. The encapsulation layer TFE may include a first encapsulation layer TFE1, a second encapsulation layer TFE2, and a third encapsulation layer TFE3.

The first encapsulation layer TFE1 may cover the emission element ED. For example, the first encapsulation layer TFE1 may cover the cathode CE, and in an embodiment, may also cover the capping pattern disposed on the cathode CE.

Referring still to FIG. 6B, a portion of the first encapsulation layer TFE1 may be disposed in the emission openings OP1-E, OP2-E, and OP3-E and the partition openings OP1-P, OP2-P, and OP3-P. The first encapsulation layer TFE1 may include a first encapsulation pattern TFE-PT1 and a second encapsulation pattern TFE-PT2. The first encapsulation pattern TFE-PT1 may cover the first partition opening OP1-P, and the second encapsulation pattern TFE-PT2 may cover the second partition opening OP2-P and the third partition opening OP3-P. The first encapsulation pattern TFE-PT1 and the second encapsulation pattern TFE-PT2 may be spaced apart from each other in a plan view. For example, the first encapsulation layer TFE1 may include an inorganic material.

The second encapsulation layer TFE2 may cover the first encapsulation layer TFE1. The second encapsulation layer TFE2 may be disposed between the first encapsulation pattern TFE-PT1 and the second encapsulation pattern TFE-PT2. The second encapsulation layer TFE2 may provide a flat top surface. The third encapsulation layer TFE3 may be disposed on the second capsulation layer TFE2. For example, the second encapsulation layer TFE2 may include an organic material, and the third encapsulation layer TFE3 may include an inorganic material.

The first encapsulation layer TFE1 and the third encapsulation layer TFE3 may protect the display element layer DP-OLED against moisture and/or oxygen, and the second encapsulation layer TFE2 may protect the display element layer DP-OLED against foreign substances.

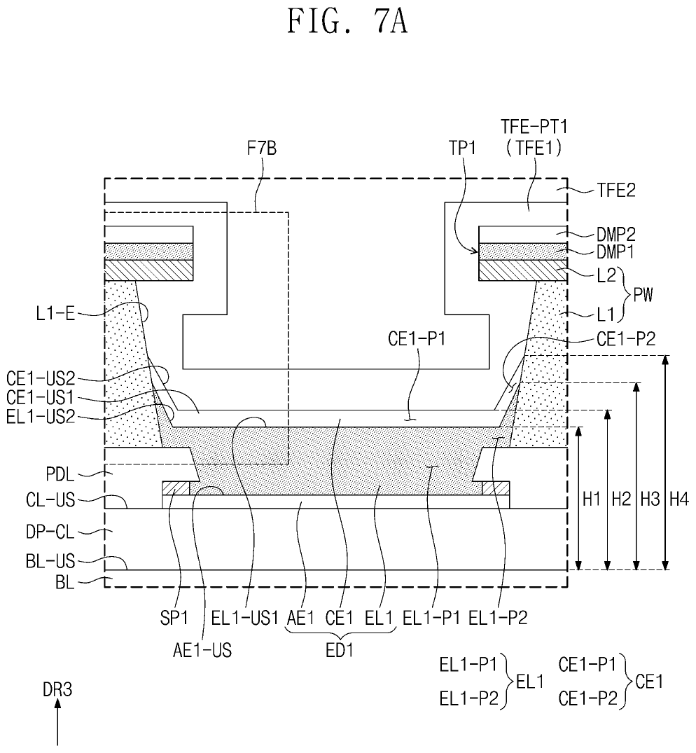

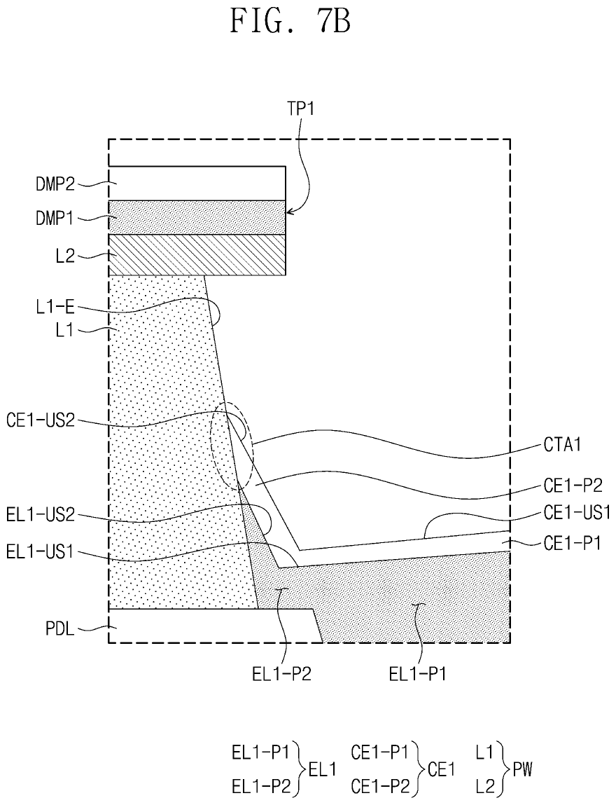

FIGS. 7A and 7B illustrate schematic enlarged cross-sectional views partially showing a display panel according to an embodiment of the disclosure. For example, FIG. 7A is an enlarged view showing section F7A of FIG. 6B, and FIG. 7B is an enlarged view showing section F7B of FIG. 7A.

Referring to FIGS. 7A and 7B, a first emission element ED1 according to an embodiment of the disclosure may include a first anode AE1, a first emission layer EL1, and a first cathode CE1.

The first emission layer EL1 may include a 1-1^{st} emission layer part EL1-P1 and a 1-2^{nd} emission layer part EL1-P2. The 1-1^{st} emission layer part EL1-P1 may be disposed on the first anode AE1, and may have a top surface EL1-US1 located at a first height H1 from a top surface BL-US of the base layer BL. The 1-2^{nd} emission layer part EL1-P2 may be disposed on the pixel definition layer PDL, and may have a top surface EL1-US2 located between the first height H1 and a third height H3 higher than the first height H1. The 1-2^{nd} emission layer part EL1-P2 may be positioned closer than the 1-1^{st} emission layer part EL1-P1 to the partition wall PW.

According to an embodiment of the disclosure, the top surface EL1-US2 of the 1-2^{nd} emission layer part EL1-P2 may be located at a height from the top surface BL-US of the base layer BL, and the height may increase with decreasing distance from the partition wall PW. For example, a second height H2 may increase with decreasing distance from the partition wall PW.

As discussed above, the 1-1^{st} emission layer part EL1-P1 and the 1-2^{nd} emission layer part EL1-P2 of the first emission layer EL1 may have a cross-sectional shape different from a cross-sectional shape of the second emission layer (see EL2 of FIG. 6B) and a cross-sectional shape of the third emission layer (see EL3 of FIG. 6B).

The first emission layer EL1 may include a first light emitting material that produces a blue color. As discussed below, a thermal evaporation process may be employed to place the first light emitting material in the first partition opening OP1-P. In thermal evaporation process, the first emission layer EL1 may be formed to include the 1-2^{nd} emission layer part EL1-P2 having the top surface EL1-US2 located at a higher position than a position of the top surface EL1-US1 of the 1-1^{st} emission layer part EP1-P1.

The first cathode CE1 may include a 1-1^{st} cathode part CE1-P1 and a 1-2^{nd} cathode part CE1-P2. The 1-1^{st} cathode part CE1-P1 may be disposed on the first emission layer EL1, and may have a top surface CE1-US1 located at the second height H2 from the top surface BL-US of the base layer BL. The 1-2^{nd} cathode part CE1-P2 may be disposed on the first emission layer EL1, and may have a top surface CE1-US2 located at a height, from the top surface BL-US of the base layer BL, between the second height H2 and a fourth height H4 higher than the second height H2. The 1-2^{nd} cathode part CE1-P2 may be positioned closer than the 1-1^{st} cathode part CE1-P1 to the partition wall PW.

According to an embodiment of the disclosure, the top surface CE1-US2 of the 1-2^{nd} cathode part CE1-P2 may be located at a height from the top surface BL-US of the base layer BL, and the height may increase with decreasing distance from the partition wall PW. For example, the fourth height H4 may increase with decreasing distance from the partition wall PW.

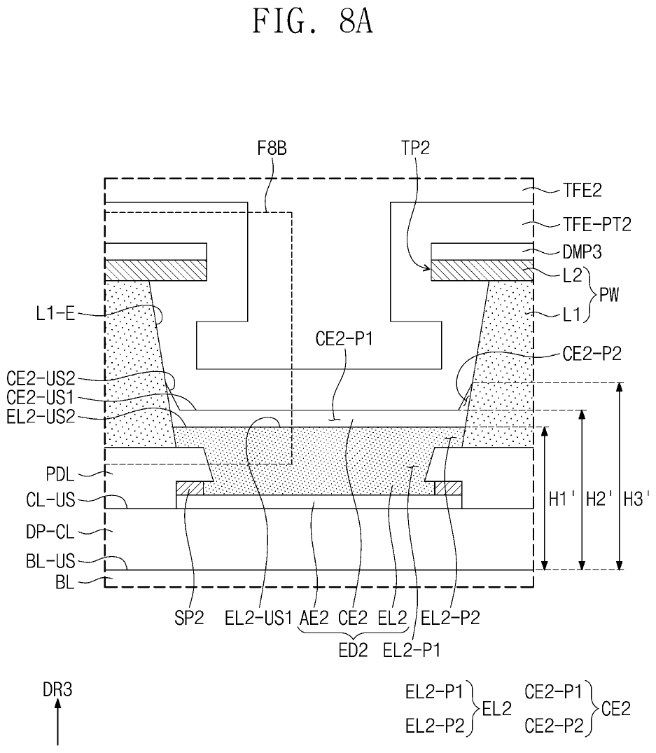

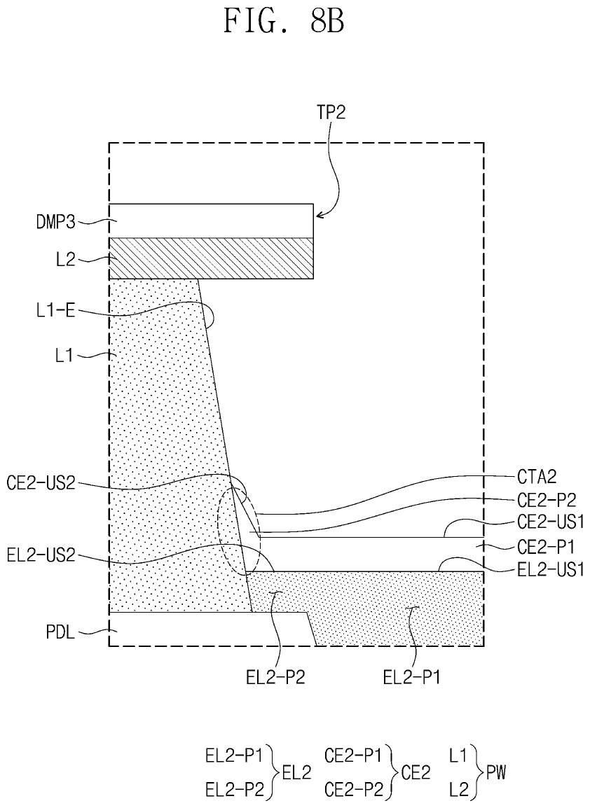

The first cathode CE1 may have a cross-sectional shape different from a cross-sectional shape of the second cathode (see CE2 of FIG. 6B) and a cross-sectional shape of the third cathode (see CE2 of FIG. 6B). However, a contact area CTA1 between the first cathode CE1 and the partition wall PW, a contact area (see CTA2 of FIG. 8B) between the second cathode CE2 and the partition wall PW, and a contact area between the third cathode CE3 and the partition wall PW may be substantially the same.

FIGS. 8A and 8B illustrate schematic enlarged cross-sectional views partially showing a display panel according to an embodiment of the disclosure. For example, FIG. 8A is an enlarged view showing section F8A of FIG. 6B, and FIG. 8B is an enlarged view showing section F8B of FIG. 8A.

Referring to FIGS. 8A and 8B, the second emission element ED2 according to an embodiment of the disclosure may include a second anode AE2, a second emission layer EL2, and a second cathode CE2.

The second emission layer EL2 may include a 2-1^{st} emission layer part EL2-P1 and a 2-2^{nd} emission layer part EL2-P2. The 2-1^{st} emission layer part EL2-P1 may be disposed on the second anode AE2, and may have a top surface EL2-US1 located at a height H1′ from the top surface BL-US of the base layer BL. The 2-2^{nd} emission layer part EL2-P2 may have a top surface EL2-US2 disposed on the pixel definition layer PDL. The 2-2^{nd} emission layer part EL2-P2 may be positioned closer than the 2-1^{st} emission layer part EL2-P1 to the partition wall PW. The 2-1^{st} emission layer part EL2-P1 and the 2-2^{nd} emission layer part EL2-P2 may be located at substantially the same height from the top surface BL-US of the base layer BL. For example, the top surface EL2-US1 of the 2-1^{st} emission layer part EL2-P1 and the top surface EL2-US2 of the 2-2^{nd} emission layer part EL2-P2 may include surfaces located at substantially the same height H1′.

According to an embodiment of the disclosure, the top surface EL2-US2 of the 2-2^{nd} emission layer part EL2-P2 may be located at the height H1′ from the top surface BL-US of the base layer BL, and the height H1′ may be changed in a direction approaching the partition wall PW. This configuration may be varied in accordance with properties of the second light emitting material included in the second emission layer EL2, but the disclosure is not limited to a certain embodiment.

The second light emitting material of the second emission layer EL2 may produce a green or red color. As discussed below, an inkjet process may be employed to place the second light emitting material in the second partition opening (see OP2-P of FIG. 6B). In the inkjet process, the second emission layer EL2 may be formed to include the 2-2^{nd} emission layer part EL2-P2 having the top surface EL2-US2. The top surface EL2-US2 of the 2-2^{nd} emission layer part EL2-P2 and the top surface EL2-US1 of the 2-1^{st} emission layer part EL2-P1 may be located at substantially the same position.

As discussed above, the 1-1^{st} emission layer part (see EL1-P1 of FIG. 7B) and the 1-2^{nd} emission layer part (see EL1-P2 of FIG. 7B) of the first emission layer (see EL1 of FIG. 7B) may have a cross-sectional shape different from a cross-sectional shape of the 2-1^{st} emission layer part EL2-P1 and the 2-2^{nd} emission layer part EL2-P2 of the second emission layer EL2.

The second cathode CE2 may include a 2-1^{st} cathode part CE2-P1 and a 2-2^{nd} cathode part CE2-P2. The 2-1^{st} cathode part CE2-P1 may be disposed on the second emission layer EL2, and may have a top surface CE2-US1 located at a second height H2′ from the top surface BL-US of the base layer BL. The 2-2^{nd} cathode part CE2-P2 may be disposed on the second emission layer EL2, and may have a top surface CE2-US2 located at a height, from the top surface BL-US of the base layer BL, between the second height H2′ and a third height H3′ higher than the second height H2′. The 2-2^{nd} cathode part CE2-P2 may be positioned closer than the 2-1^{st} cathode part CE2-P1 to the partition wall PW.

According to an embodiment of the disclosure, the top surface CE2-US2 of the 2-2^{nd} cathode part CE2-P2 may be located at a height from the top surface BL-US of the base layer BL, and the height may increase with decreasing distance from the partition wall PW. The third height H3′ may increase with decreasing distance from the partition wall PW.

A cross-sectional shape of the second cathode CE2 and a cross-sectional shape of the first cathode (see CE1 of FIG. 7B) may be different from each other. A contact area CTA2 between the second cathode CE2 and the partition wall PW and the contact area (see CTA1 of FIG. 7B) between the first cathode (see CE1 of FIG. 7B) and the partition wall PW may be substantially the same.

FIGS. 8A and 8B schematically illustrate the second emission element ED2, and the configuration and arrangement of the second emission element ED2 may also be applicable to a configuration and arrangement of the third emission element (see ED3 of FIG. 6B).

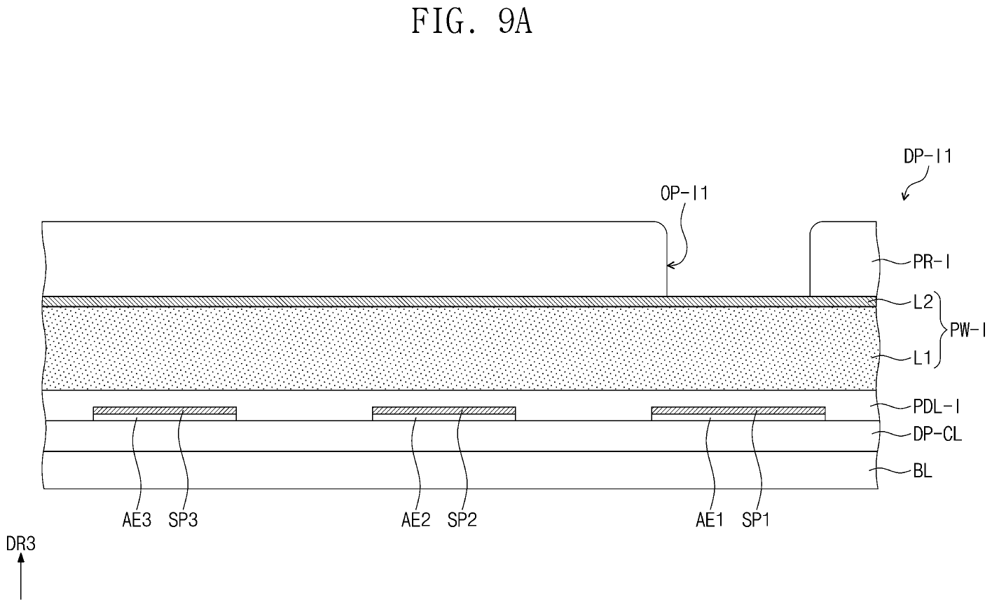

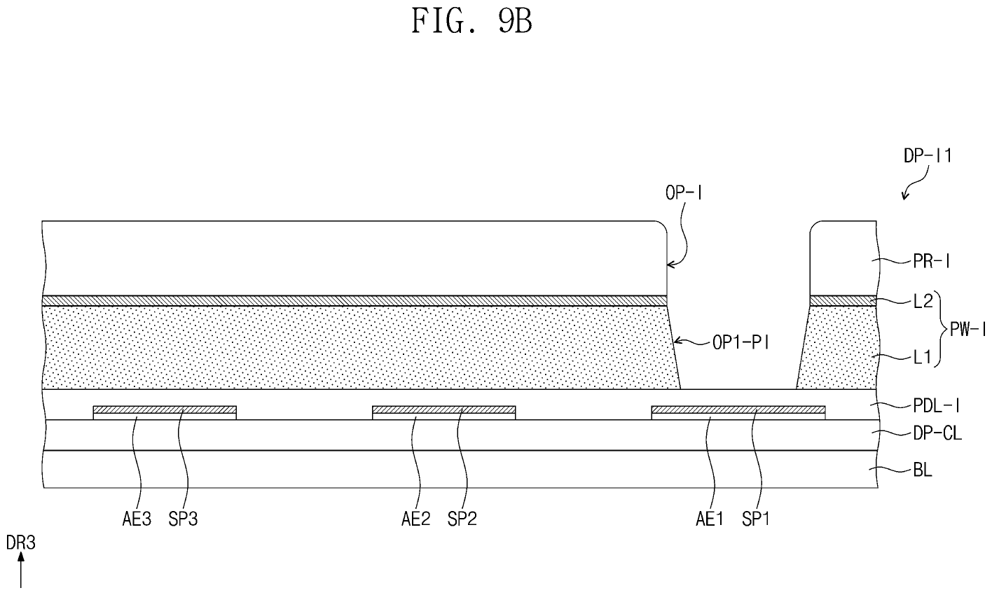

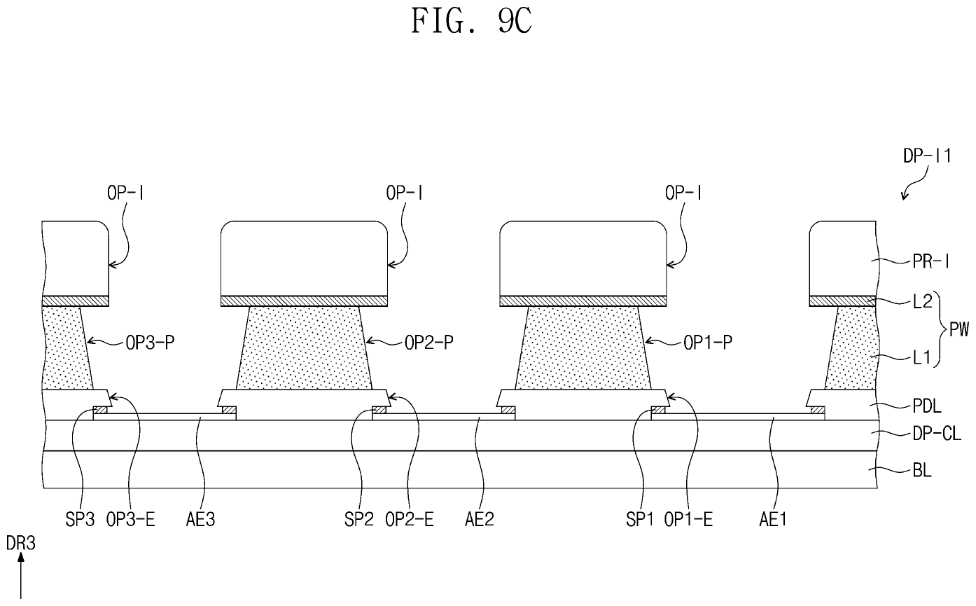

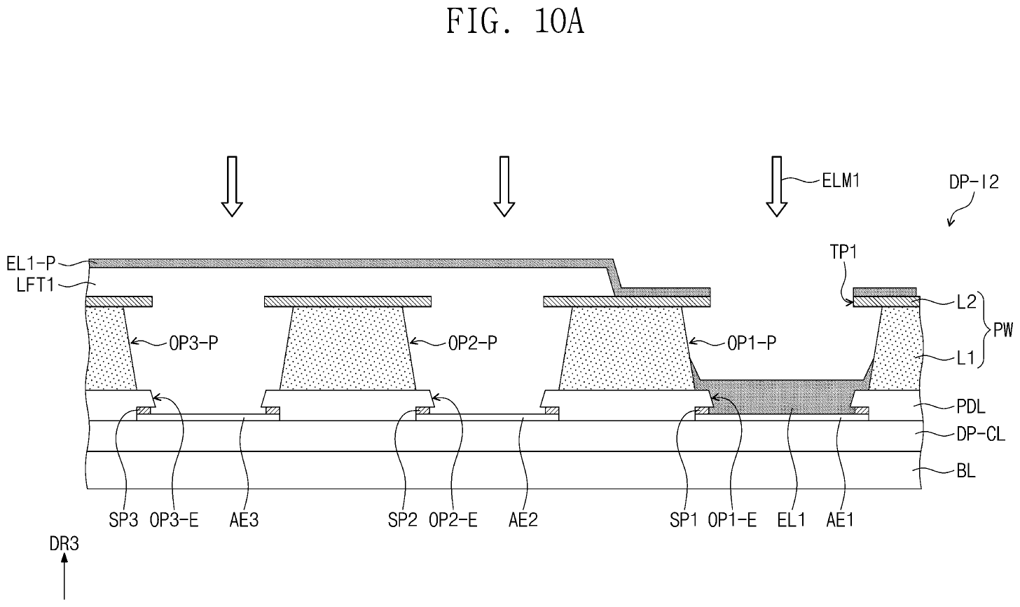

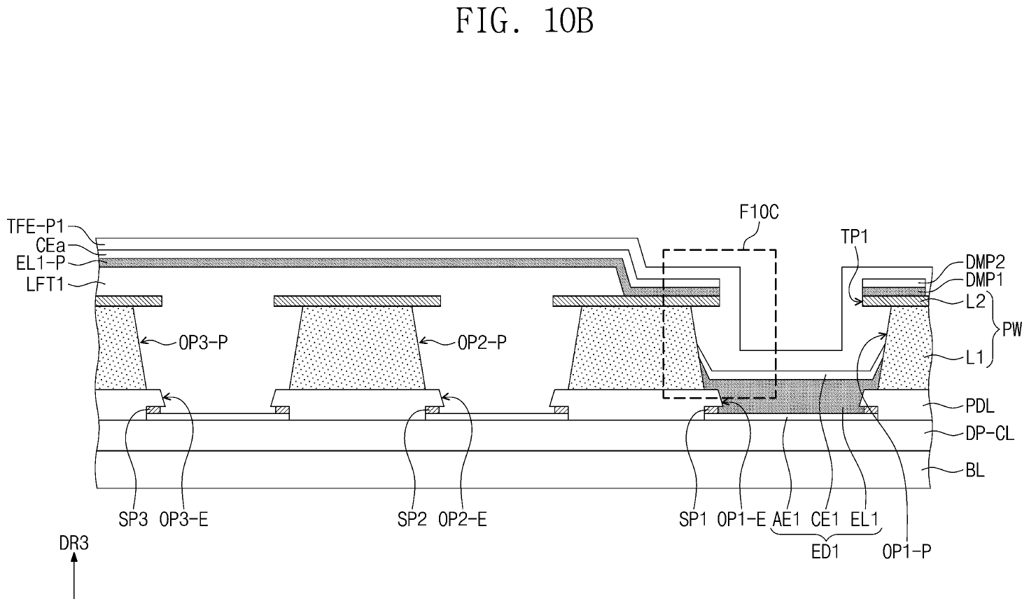

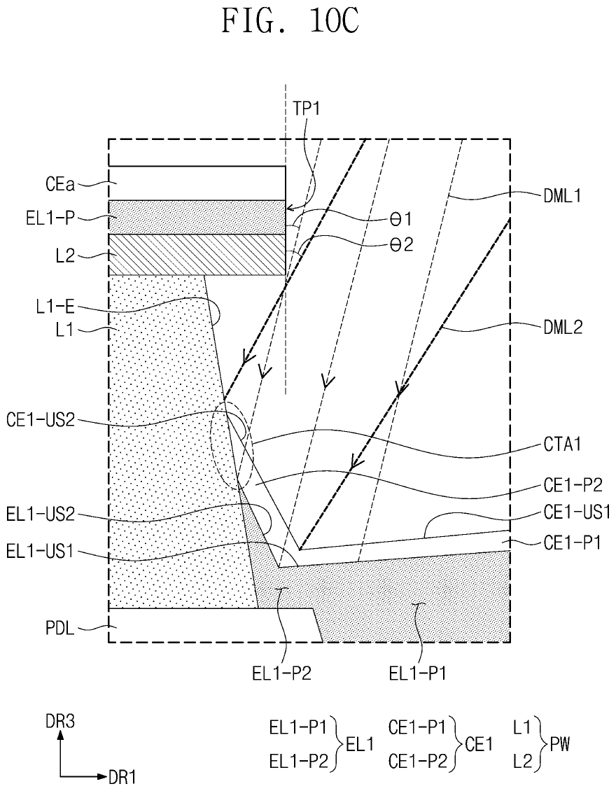

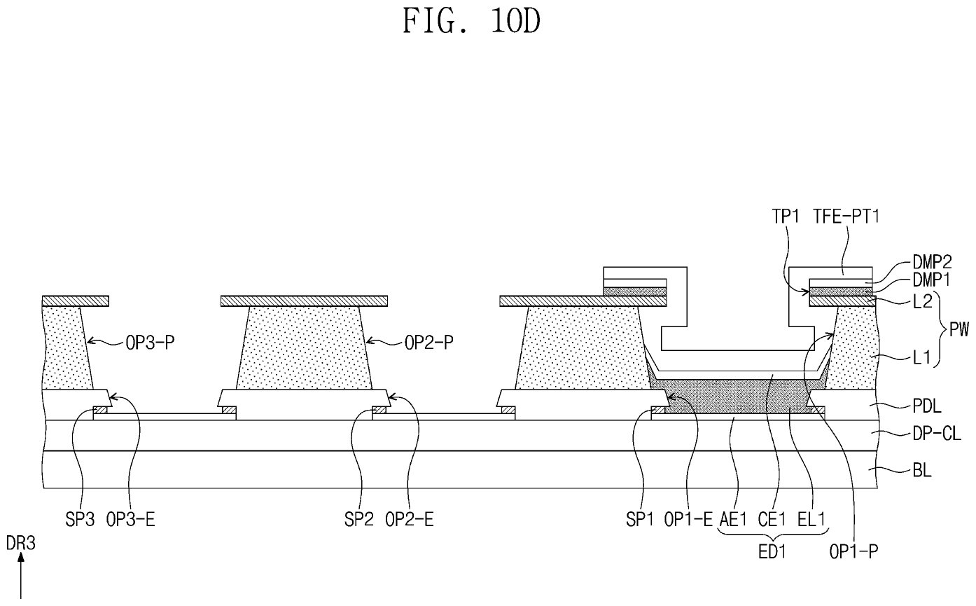

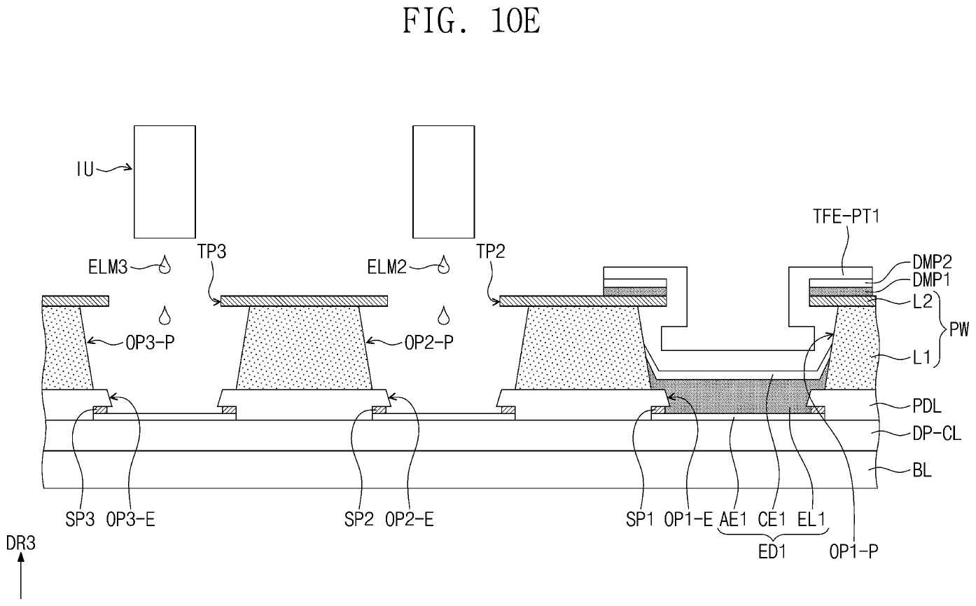

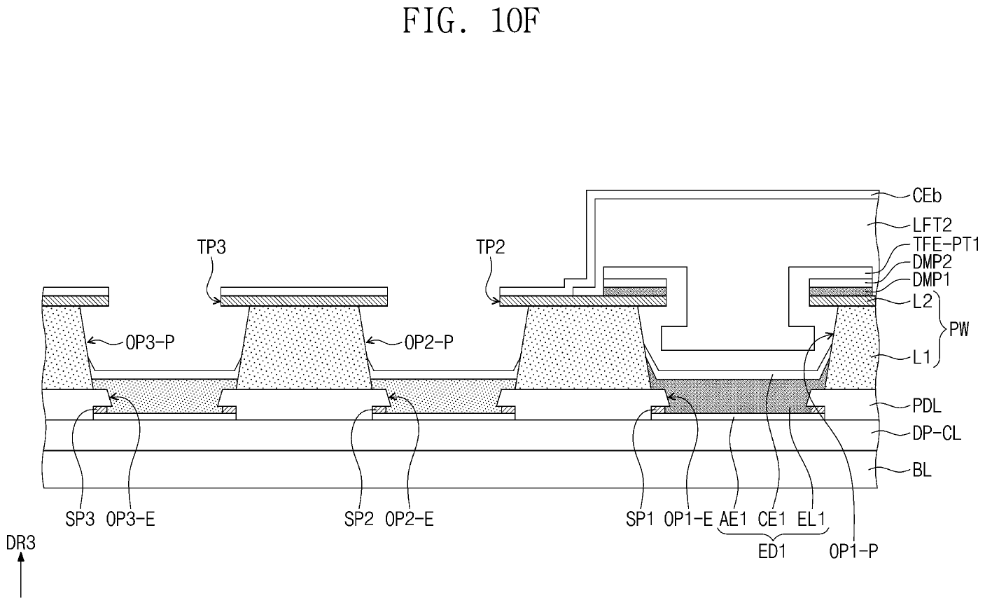

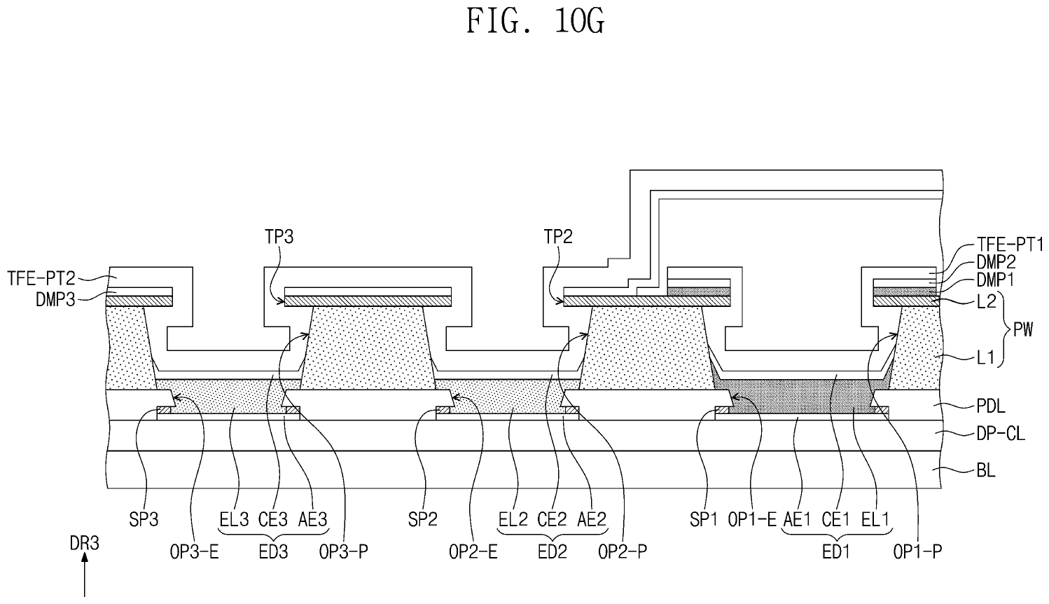

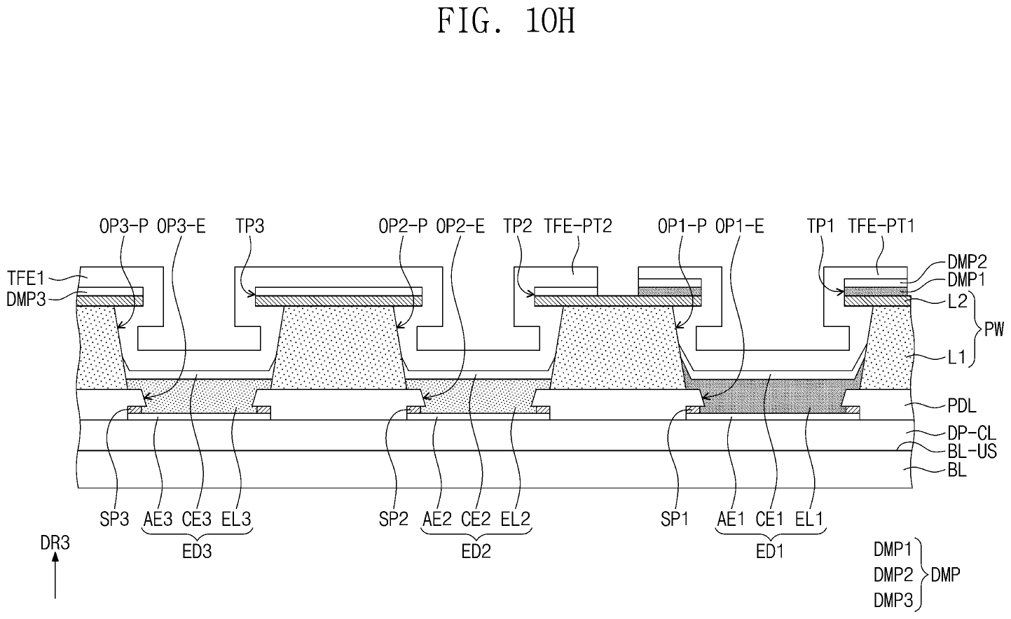

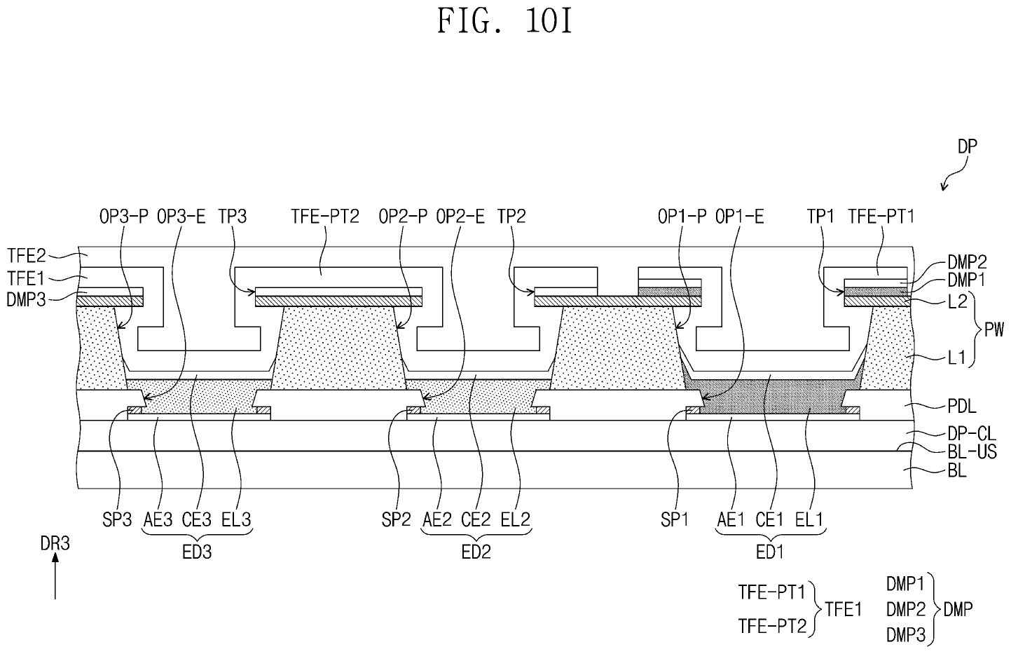

FIGS. 9A to 9C and 10A to 10I illustrate schematic cross-sectional views partially showing a method of fabricating a display panel according to an embodiment of the disclosure. The same or like components as those discussed in FIGS. 1 to 8B will be allocated the same or like reference symbols, and any repetitive description thereof will be omitted.

According to an embodiment of the disclosure, a method of fabricating a display panel may include providing a preliminary display panel including a base layer, an anode, and a preliminary pixel definition layer, forming a partition wall in which multiple partition openings are formed, patterning the preliminary pixel definition layer to define a pixel definition layer in which an emission opening is formed, and forming a first emission layer, a second emission layer, a third emission layer, a first cathode, a second cathode, and a third cathode.

A method of fabricating a display panel according to an embodiment of the disclosure may include forming a first encapsulation layer that includes a first encapsulation pattern covering a first emission opening and a second encapsulation pattern, which is separated from the first encapsulation pattern, covering a second emission opening and a second emission opening, and forming a second encapsulation layer that covers the first encapsulation layer.

With reference to FIGS. 9A to 10I, the following will describe a method of forming emission elements ED1, ED2, and ED3 and first and second encapsulation layers TFE1 and TFE2 that cover the emission elements ED1, ED2, and ED3.

Referring to FIG. 9A, an initial photoresist layer PR-I may be formed on a first preliminary display panel DP-11.

In an embodiment, the first preliminary display panel DP-11 may include a base layer BL, a circuit element layer DP-CL, first, second, and third anodes AE1, AE2, and AE3, first, second, and third sacrificial patterns SP1, SP2, and SP3, a preliminary pixel definition layer PDL-I, and a preliminary conductive partition layer PW-I.

The circuit element layer DP-CL may be formed by a circuit fabrication process in which coating and deposition processes are employed to form a dielectric layer, a semiconductor layer, and a conductive layer, and in which photolithography and etching processes are performed to selectively pattern the dielectric layer, the semiconductor layer, and the conductive layer to form a semiconductor pattern, a conductive pattern, and a signal line.

The anodes AE1, AE2, and AE3 and the sacrificial patterns SP1, SP2, and SP3 may be formed by a same patterning process. The preliminary pixel definition layer PDL-I may cover all of the anodes AE1, AE2, and AE3 and the sacrificial patterns SP1, SP2, and SP3.

The preliminary conductive partition layer PW-I may include a first partition layer L1 and a second partition layer L2 disposed on the first partition layer L1. The first partition layer L1 may have a first conductivity and a first thickness, and the second partition layer L2 may have a second conductivity lower than the first conductivity and a second thickness less than the first thickness.

The initial photoresist layer PR-I may be formed by forming a preliminary layer on the preliminary conductive partition layer PW-I, and using a photomask to pattern the preliminary photoresist layer. The patterning process may cause the initial photoresist layer PR-I to have an initial opening OP-11 that is formed to overlap the first anode AE1 in a plan view.

Referring to FIGS. 9B and 9C, a first etching process may be performed such that the preliminary conductive partition layer may be formed into a conductive partition wall in which a partition opening is defined.

As shown in FIG. 9B, the first etching process may include using the initial photoresist layer PR-I as a mask to dry-etching the first and second partition layers L1 and L2 to form a first preliminary partition opening OP1-P1 in the preliminary conductive partition layer PW-I. The dry etching step of the first etching process may be performed in an etching environment where substantially the same etch selectivity is provided between the first and second partition layers L1 and L2. Therefore, the first partition layer L1 and the second partition layer L2 may have inner lateral surfaces that define the first preliminary partition opening OP1-P1, and the inner lateral surfaces may be substantially aligned with each other.

As shown in FIG. 9B, the first etching process may include using the initial photoresist layer PR-I as a mask to wet-etch the first and second partition layers L1 and L2 to form the first preliminary partition opening OP1-P1 into a first partition opening OP1-P. Thus, a conductive partition wall PW may be formed from the preliminary conductive partition layer PW-I in which the first preliminary partition opening OP1-P1.

The wet etching step of the first etching process may be performed in an environment where a high etch selectivity is provided between the first and second partition layers L1 and L2. Therefore, in a cross-sectional view, an undercut shape may be formed to an inner lateral surface of the partition wall PW that defines the first partition opening OP1-P. For example, compared to the second partition layer L2, the first partition layer L1 may have a high etch rate with respect to an etching solution, and thus the first partition layer L1 may be more etched. Accordingly, an inner lateral surface of the first partition layer L1 may be formed recessed more than an inner lateral surface of the second partition layer L2. The second partition layer L2 may include a portion that protrudes from the first partition layer L1, and the protruding portion of the second partition layer L2 may be defined as a tip of the conductive partition wall PW.

A second etching process may be performed such that the preliminary definition layer PDL-I may be patterned to form a pixel definition layer PDL in which a first emission opening OP1-E is defined. The second etching process may be executed in a dry etching manner, and the initial photoresist layer PR-I and the conductive partition wall (e.g., the second partition layer L2) may be used as a mask in the second etching process.

Moreover, in an embodiment, a third etching process may be performed to form a first sacrificial opening OP1-S in the first sacrificial pattern SP1 so as to expose at least a portion of the first anode AE1. The third etching process may be executed in a wet etching manner, and the initial photoresist layer PR-I and the pixel definition layer PDL having the first emission opening OP1-E defined therein may be used as a mask in the third etching process. The first sacrificial pattern SP1 may include an azo compound. The first sacrificial pattern SP1 may be zinc oxide (ZnOₓ) doped with aluminum (Al). A content of aluminum (Al) may range from about 2 at % to about 5 at %. In another embodiment, the first sacrificial pattern SP1 may include gallium zinc oxide (GZO).

The first sacrificial pattern SP1 may have an inner lateral surface that defines the first sacrificial opening OP1-S, and the pixel definition layer PDL may have an inner lateral surface that defines the first emission opening OP1-E. The inner lateral surface of the first sacrificial pattern SP1 may be inwardly recessed more than the inner lateral surface of the pixel definition layer PDL. The inner lateral surface of the first sacrificial pattern SP1 may be aligned with the inner lateral surface of the pixel definition layer PDL, but the disclosure is not limited to a certain embodiment.

The third etching process may be executed in an environment where a high etch selectivity is provided between the first sacrificial pattern SP1 and the first anode AE1, and thus the first anode AE1 may be prevented from being etched. For example, the first sacrificial pattern SP1 whose etch rate is greater than etch rate of the first anode AE1 may be disposed between the pixel definition layer PDL and the first anode AE1, and therefore the first anode AE1 may be prevented from being etched and damaged during an etching process. For example, the first sacrificial pattern SP1 including an azo compound may have an etch rate of about 370 Å/see, and the first partition layer L1 may have an etch rate of about 19 Å/sec. The etch rate of the first sacrificial pattern SP1 may be about 18 times to about 30 times the etch rate of the first partition layer L1. Accordingly, etching loss of the partition wall PW may be reduced.

The third etching process may be performed separately from or simultaneously with the second etching process.

According to an embodiment, the initial photoresist layer PR-I may be removed. In an embodiment, after the removal of the initial photoresist layer PR-I, a second preliminary display panel DP-12 (referred to as a preliminary display panel in Claims) may be provided. For example, the second preliminary display panel DP-12 may include the base layer BL, the circuit element layer DP-CL, the first, second, and third anodes AE1, AE2, and AE3, the pixel definition layer PDL in which the first emission opening OP1-E is defined, and the conductive partition wall PW in which the first partition opening OP1-P is defined.

According to an embodiment of the disclosure, after the formation of the first partition opening OP1-P, a second partition opening OP2-P and a third partition opening OP3-P may be formed. The second partition opening OP2-P, the third partition opening OP3-P, and the first partition opening OP1-P may be formed through a same process. After the formation of the first emission opening OP1-E, a second emission opening OP2-E and a third emission opening OP3-E may be formed. The second emission opening OP2-E, the third emission opening OP3-E and the first emission opening OP1-E may be formed through a same process. In another embodiment, the second partition opening OP2-P and the third partition opening OP3-P may be formed simultaneously with the first partition opening OP1-P, and the second emission opening OP2-E and the third emission opening OP3-E may be formed simultaneously with the first emission opening OP1-E, but the disclosure is not limited to a certain embodiment.

Although the sacrificial patterns SP1, SP2, and SP3 are illustrated in figures, the disclosure is not limited thereto, and in another embodiment, the sacrificial patterns SP1, SP2, and SP3 may be omitted.

Referring to FIGS. 10A to 10D, a method of fabricating a display panel according to an embodiment of the disclosure may include forming a first emission layer EL1, forming a first cathode CE1, and forming a first encapsulation pattern TFE-PT1.

Referring to FIG. 10A, the formation of the first emission layer EL1 may include forming a first emission pattern EL1-P on the second preliminary display panel DP-12 from which the initial photoresist layer (see PR-I of FIG. 9C) is removed. A deposition process may be performed to form the first emission pattern EL1-P. In an embodiment, a thermal evaporation process may be performed to form the first emission pattern EL1-P. For example, the first emission pattern EL1-P may be formed by a vacuum thermal evaporation.

According to an embodiment of the disclosure, before the formation of the first emission pattern EL1-P, a first lift member LFT1 may be formed to cover the second partition opening OP2-P and a portion of the partition wall PW. The first emission pattern EL1-P may be disposed on the first lift member LFT1.

In the formation of the first emission pattern EL1-P, the first emission pattern EL1-P may be divided by a tip TP1 formed in the partition wall PW, and thus the first emission layer EL1 may be disposed in the first emission opening OP1-E and the first partition opening OP1-E.

According to an embodiment of the disclosure, the first emission pattern EL1-P may include a first light emitting material ELM1 that generates blue light. A thermal evaporation process, not an inkjet process, may be performed to use the first light emitting material ELM1 to form the first emission pattern EL1-P, and thus the first light emitting material ELM1 may improve in lifespan properties. The first light emitting material ELM1 may be thermally deposited to form the first emission pattern EL1-P and the first emission layer EL1, and thus a 1-1^{st} emission layer part (see EL1-P1 of FIG. 7B) and a 1-2^{st} emission layer part (see EL1-P2 of FIG. 7B) may be formed.

Referring to FIG. 10B, the formation of the first cathode CE1 may include forming a first cathode pattern CEa on the first emission pattern EL1-P. A deposition process may be performed to form the first cathode pattern CEa. For example, a sputtering process may be performed to form the first cathode pattern CEa, but the disclosure is not limited thereto.

In the formation of the first cathode pattern CEa, the first cathode pattern CEa may be divided by the tip TP1 formed in the partition wall PW, and may be disposed in the first partition opening OP1-P.

The formation of the first encapsulation pattern TFE-PT1 may include forming a first preliminary encapsulation pattern TFE-P1 on the first cathode pattern CEa. The first preliminary encapsulation pattern TFE-P1 may be formed by a deposition process. In an embodiment, the first preliminary encapsulation pattern TFE-P1 may be formed by a chemical vapor deposition (CVD) process. The first preliminary encapsulation pattern TFE-P1 may be formed on the partition wall PW and the first cathode pattern CEa, and a portion of the first preliminary encapsulation pattern TFE-P1 may be formed inside the first partition opening OP1-P.

FIG. 10C illustrates an enlarged view showing section F10C of FIG. 10B.

Referring to FIG. 10C, according to an embodiment of the disclosure, a deposition angle of the first cathode pattern CEa may be different from a deposition angle of the first emission pattern EL1-P.

A deposition incident angle θ2 of the first cathode pattern CEa may be greater than a deposition incident angle θ1 of the first emission pattern EL1-P, and thus a 1-2^{nd} cathode part CE1-P2 may be formed to contact an inner lateral surface L1-E of the first partition layer L1. As illustrated in FIG. 10C, the first emission pattern EL1-P may be deposited along a first deposition direction line DML1 having a deposition angle, and the 1-2^{nd} cathode part CE1-P2 may be deposited along a second deposition direction line DML2. Therefore, the 1-2^{nd} cathode part CE1-P2 may be disposed on and in contact with an upper portion of the second emission part EL1-P2 of the first emission pattern EL1-P, which second emission part EL1-P2 is formed along the inner lateral surface L1-E of the first partition layer L1. Accordingly, it may be possible to secure reliability of a first cathode CE1 which will be discussed below.

Referring to FIGS. 10B and 10D, according to an embodiment of the disclosure, the first preliminary encapsulation pattern TFE-P1 may be patterned to form the first encapsulation pattern TFE-PT1.

The patterning of the first preliminary encapsulation pattern TFE-P1 may remove the first lift member LFT1, a portion of the first emission pattern EL1-P, a portion of the first cathode pattern CEa, and a portion of the first preliminary encapsulation pattern TFE-P1. For example, the first lift member LFT1 may be removed, and the first emission pattern EL1-P, the first cathode pattern CEa, and the first preliminary encapsulation pattern TFE-P1 may each be partially removed.

According to an embodiment of the disclosure, after the removal of the first lift member LFT1, an upper portion of the partition wall PW may be additionally polished or worked, but the disclosure is not limited to a certain embodiment.

However, a method of fabricating a display panel according to an embodiment of the disclosure is not limited to the patterning process in which the first lift member LFT1 is disposed on the first partition opening OP1-P, the second partition opening OP2-P, and the partition wall PW, and in which the first lift member LFT1 is removed and simultaneously the first preliminary encapsulation pattern TFE-P1 is removed, and it may be possible to adopt an etching process instead of the patterning process, but the disclosure is not limited to a certain embodiment.

Referring to FIG. 10E, a method of fabricating a display panel according to an embodiment of the disclosure may include forming a second emission layer EL2 and a third emission layer EL3.

In the formation of the second emission layer EL2 and the third emission layer EL3, the second emission layer EL2 and the third emission layer EL3 may be formed on the second anode AE2 and the third anode AE3. In an embodiment, an inkjet process may be performed to form the second emission layer EL2 and the third emission layer EL3. An ink injection unit may be used to inject a second light emitting material ELM2 and a third light emitting material ELM3 on the second anode AE2 and the third anode AE3. The second light emitting material ELM2 and the third light emitting material ELM3 may be respectively accommodated in the second partition opening OP2-P and the third partition opening OP3-P.

In the formation of the second emission layer EL2 and the third emission layer EL3, tips TP2 and TP3 may prevent the second light emitting material ELM2 and the third light emitting material ELM3 from respectively departing from the second partition opening OP2-P and the third partition opening OP3-P.

The second emission layer EL2 and the third emission layer EL3 may be formed simultaneously with each other in a same step or separately from each other in different steps, but the disclosure is limited to a certain embodiment.

According to an embodiment of the disclosure, the second light emitting material ELM2 included in the second emission layer EL2 may generate light having one of green and red colors, and the third light emitting material ELM3 included in the third emission layer EL3 may generate light having another one of green and red colors.

An inkjet process, not a thermal evaporation process, may be performed to use the second light emitting material ELM2 to form the second emission layer EL2 and the third light emitting material ELM3 to form the third emission layer EL3. In case that the inkjet process is used instead of the thermal evaporation process, although there is a partial reduction in lifespan properties of the second emission layer EL2 and the third emission layer EL3, there may be no significant decrease in lifespan properties, but rather there may be an increase in process efficiency and a reduction in manufacturing cost.

Referring to FIG. 10F, a method of fabricating a display panel according to an embodiment of the disclosure may include forming a second cathode pattern CEb.

The second cathode pattern CEb may be formed by a deposition process. For example, the second cathode pattern CEb may be formed by a sputtering process, but the disclosure is not limited thereto.

In the formation of the second cathode pattern CEb, the second cathode pattern CEb may be divided by the tips TP2 and TP3 formed in the partition wall PW, and may be disposed in the second partition opening OP2-P and the third partition opening OP3-P. Compared to a second emission pattern and a third emission pattern, the second cathode pattern CEb may be provided at a deposition incident angle, and may thus be formed to contact the inner lateral surface (see L1-E of FIG. 10C) of the first partition layer L1.

According to an embodiment of the disclosure, before the formation of the second cathode pattern CEb, a second lift member LFT2 may be formed to cover the first encapsulation pattern TFE-PT1. The second cathode pattern CEb may be disposed on the second lift member LFT2.

Referring to FIG. 10G, a method of fabricating a display panel according to an embodiment of the disclosure may include forming a second preliminary encapsulation pattern TFE-P2.

The second preliminary encapsulation pattern TFE-P2 may be formed by a deposition process. In an embodiment, the second preliminary encapsulation pattern TFE-P2 may be formed by a chemical vapor deposition process. The second preliminary encapsulation pattern TFE-P2 may be formed on the second cathode pattern CEb or the partition wall PW, and a portion of the second preliminary encapsulation pattern TFE-P2 may be formed inside the second and third partition openings OP2-P and OP3-P.

Referring to FIG. 10H, a method of fabricating a display panel according to an embodiment of the disclosure may include patterning the second preliminary encapsulation pattern TFE-P2.

The patterning of the second preliminary encapsulation pattern TFE-P2 may remove the second lift member (see LFT2 of FIG. 10F) disposed on the first encapsulation pattern TFE-PT1, a portion of the second cathode pattern (see CEb of FIG. 10F), and a portion of the second preliminary encapsulation pattern (see TFE-P2 of FIG. 10G). For example, the second lift member (see LFT2 of FIG. 10F) may be removed, and the second cathode pattern (see CEb of FIG. 10F) and the second preliminary encapsulation pattern (see TFE-P2 of FIG. 10G) may each be partially removed. However, a method of fabricating a display panel according to an embodiment of the disclosure is not limited to the patterning process in which the second lift member (see LFT2 of FIG. 10F) is disposed on the first encapsulation pattern TFE-PT1, and in which the second lift member (see LFT2 of FIG. 10F) is removed and simultaneously the second cathode pattern (see CEb of FIG. 10F) and the second preliminary encapsulation pattern TFE-P2 are removed, and for example as shown in figures, it may be possible, but not limited to, to adopt a patterning process, or an etching process, in which the first encapsulation pattern (see LFT1 of FIG. 10B) and the second encapsulation pattern (see LFT2 of FIG. 10F) can be spaced apart or separated from each other.

Referring to FIG. 10I, a method of fabricating a display panel according to an embodiment of the disclosure may include forming a second encapsulation layer TFE2.

The second encapsulation layer TFE2 may be formed on the first encapsulation layer TFE1. The second encapsulation layer TFE2 may cover the first encapsulation pattern TFE-PT1, the second encapsulation pattern TFE-PT2, and the partition wall PW that is not covered with any of the first and second encapsulation patterns TFE-PT1 and TFE-PT2.

The second encapsulation layer TFE2 may be formed by using an inkjet process to coat an organic material, but the disclosure is not limited thereto. The second encapsulation layer TFE2 may provide a planarized top surface.

A third encapsulation layer may be formed on the second encapsulation layer TFE2. An inorganic material may be deposited to form the third encapsulation layer. Accordingly, a display panel DP may be formed.

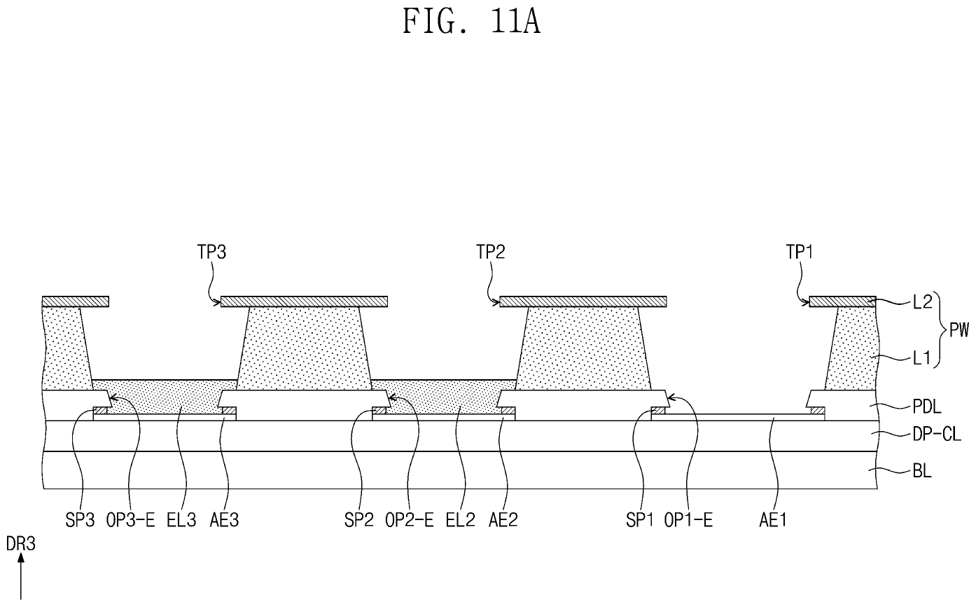

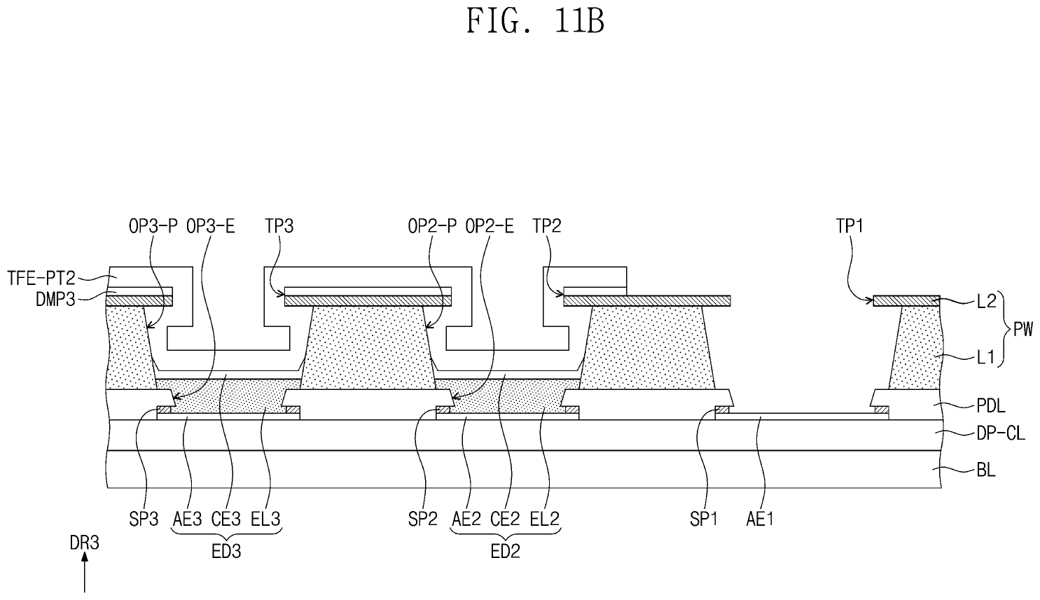

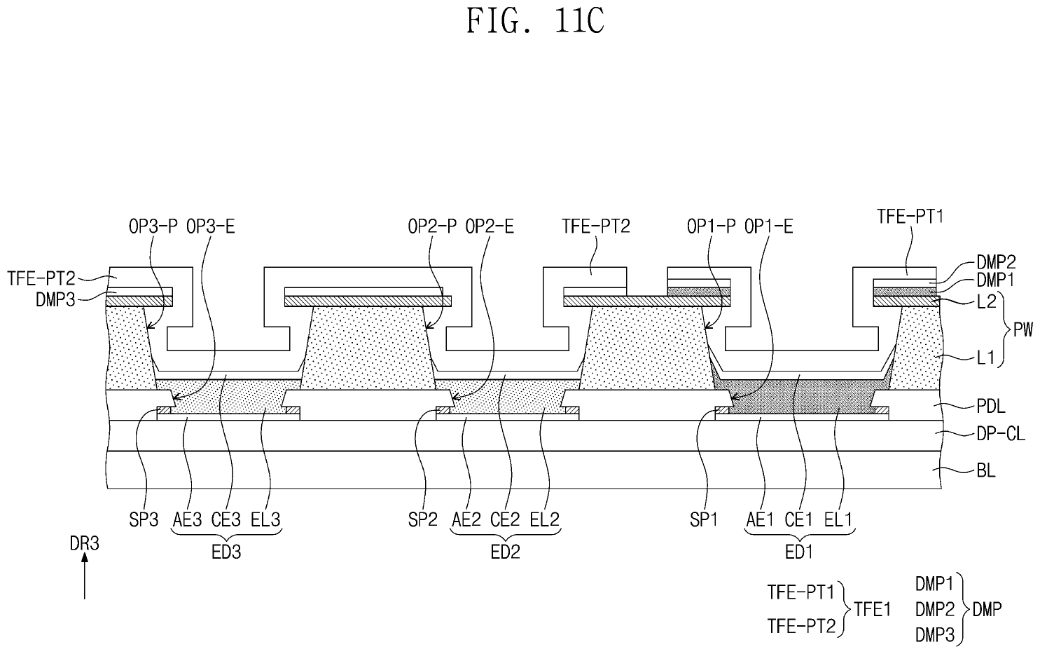

FIGS. 11A to 11C illustrate schematic cross-sectional views partially showing a method of fabricating a display panel according to an embodiment of the disclosure. FIGS. 11A to 11C show an embodiment having a different process sequence from a process sequence of a method of fabricating a display panel according to an embodiment depicted in FIGS. 10A to 10I. The same or like components as those discussed in FIGS. 1 to 10I will be allocated the same or like reference symbols, and any repetitive description thereof will be omitted.

Referring to FIG. 11A, a method of fabricating a display panel according to an embodiment of the disclosure may include forming a second emission layer EL2 and a third emission layer EL3.

Differently from that discussed in FIGS. 10A to 10I, the formation of the second emission layer EL2 and the third emission layer EL3 may be followed by the formation of the first emission layer EL1. An inkjet process may be performed to form the second emission layer EL2 and the third emission layer EL3.

A second light emitting material included in the second emission layer EL2 may generate light having one of green and red colors, and a third light emitting material included in the third emission layer EL3 may generate light having another one of green and red colors.

Referring to FIG. 11B, a method of fabricating a display panel according to an embodiment of the disclosure may include forming a second cathode CE2, a third cathode CE3, and a second encapsulation pattern TFE-PT2.

Differently from that discussed in FIGS. 10A to 10I, the formation of the second cathode CE2, the third cathode CE3, and the second encapsulation pattern TFE-PT2 may be followed by the formation of the first cathode CE1 and the first encapsulation pattern TFE-PT1.

Although a lift member is used to form the second encapsulation pattern TFE-PT2, the disclosure is not limited thereto, and in another embodiment, an etching process may be employed to pattern the second encapsulation pattern TFE-PT2.

Referring to FIG. 11C, a method of fabricating a display panel according to an embodiment of the disclosure may include forming a first encapsulation pattern TFE-PT1.

According to an embodiment of the disclosure, after the formation of the second encapsulation pattern TFE-PT2, a first emission layer EL1, a first cathode CE1, and a first encapsulation pattern TFE-PT1 may be formed. In a plan view, the first encapsulation pattern TFE-PT1 may be spaced apart from the second encapsulation pattern TFE-PT2.

The first emission layer EL1 may be formed by a thermal evaporation process and a patterning process, the first cathode CE1 may be formed by a sputtering process and a patterning process, and the first encapsulation pattern TFE-PT1 may be formed by a chemical vapor deposition process and a patterning process, but the disclosure is not limited to a certain embodiment.

A first light emitting material included in the first emission layer EL1 may generate light of a blue color.

Although a lift member is used to form the first encapsulation pattern TFE-PT1, the disclosure is not limited thereto, and in another embodiment, an etching process may be employed to pattern the first encapsulation pattern TFE-PT1.

In a display panel and a method of fabricating the same in accordance with one embodiment of the disclosure, an emissions element may be formed without using a metal mask.

In a display panel and a method of fabricating the same in accordance with an embodiment of the disclosure, an emission element may be formed whose process reliability is increased.

In a display panel and a method of fabricating the same in accordance with an embodiment of the disclosure, a light emitting material may be inkjet-coated to increase process efficiency and to reduce manufacturing cost.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display panel, comprising:
a base layer;
a pixel definition layer on the base layer and including a plurality of emission openings that are spaced apart from each other;
a partition wall on the pixel definition layer and including a plurality of partition openings that overlap the plurality of emission openings in a plan view, the partition wall having conductivity;
a first emission element in a first emission opening of the plurality of emission openings, the first emission element including a first anode, a first emission layer on the first anode and including a light emitting material that generates light of a first color, and a first cathode on the first emission layer and coupled to the partition wall; and
a second emission element in a second emission opening of the plurality of emission openings, the second emission element including a second anode, a second emission layer on the second anode and including a light emitting material that generates light of a second color different from the first color, and a second cathode on the second emission layer and coupled to the partition wall,
wherein a contact area between the first emission layer and the partition wall and a contact area between the second emission layer and the partition wall are different from each other.

2. The display panel of claim 1, wherein a cross-sectional shape of a portion of the first emission layer contacting the partition wall and a cross-sectional shape of a portion of the second emission layer contacting the partition wall are different from each other.

3. The display panel of claim 1, wherein
the first emission layer includes:
a first emission layer part on the first anode and having a top surface at a first height from a top surface of the base layer; and
a second emission layer part on the pixel definition layer and having a top surface at a second height from the top surface of the base layer higher than the first height, and
the second height of the top surface of the second emission layer part increases with decreasing distance from the partition wall.

4. The display panel of claim 1, wherein
the second cathode includes:
a first cathode part on the second emission layer and having a top surface at a third height from a top surface of the base layer; and
a second cathode part on the second emission layer and having a top surface at a fourth height from the top surface of the base layer higher than the third height, and
the fourth height of the top surface of the second cathode part increases with decreasing distance from the partition wall.

5. The display panel of claim 1, wherein the first color is a blue color.

6. The display panel of claim 1, further comprising:
a first encapsulation layer that includes a first encapsulation pattern covering the first emission opening and a second encapsulation pattern covering the second emission opening; and
a second encapsulation layer that covers the first encapsulation layer.

7. The display panel of claim 6, further comprising:
a third emission element in a third emission opening of the plurality of emission openings, the third emission element including a third anode, a third emission layer on the third anode and including a light emitting material that generates light of a third color different from the first color, and a third cathode on the third emission layer and coupled to the partition wall, wherein
the second color is one of green and red colors, and
the third color is another one of green and red colors.

8. The display panel of claim 7, wherein the second encapsulation pattern further covers the third emission element.

9. The display panel of claim 7, wherein a cross-sectional shape of a portion of the second emission layer contacting partition wall and a cross-sectional shape of a portion of the third emission layer contacting partition wall are substantially same.

10. A display panel, comprising:
a base layer;
a pixel definition layer on the base layer and including a plurality of emission openings that are spaced apart from each other;
a partition wall on the pixel definition layer and including a plurality of partition openings that overlap the plurality of emission openings in a plan view, the partition wall having conductivity;
a first emission element in a first emission opening of the plurality of emission openings, the first emission element including a first anode, a first emission layer on the first anode and including a light emitting material that generates light of a first color, and a first cathode on the first emission layer and coupled to the partition wall;
a second emission element in a second emission opening of the plurality of emission openings, the second emission element including a second anode, a second emission layer on the second anode and including a light emitting material that generates light of a second color different from the first color, and a second cathode on the second emission layer and coupled to the partition wall;
a third emission element in a third emission opening of the plurality of emission openings, the third emission element including a third anode, a third emission layer on the third anode and including a light emitting material that generates light of a third color different from the first color, and a third cathode on the third emission layer and coupled to the partition wall; and
a first encapsulation layer that includes a first encapsulation pattern covering the first emission opening and a second encapsulation pattern spaced apart from the first encapsulation pattern, the second encapsulation pattern covering the second and third emission openings.

11. The display panel of claim 10, further comprising:
a second encapsulation layer that covers the first encapsulation pattern and the second encapsulation pattern.

12. The display panel of claim 10, wherein
a cross-sectional shape of a portion of the first emission layer contacting the partition wall and a cross-sectional shape of a portion of the second emission layer contacting the partition wall are different from each other, and
the cross-sectional shape of the portion of the second emission layer contacting the partition wall and a cross-sectional shape of a portion of the third emission layer contacting the partition wall are substantially same.

13. The display panel of claim 12, wherein
the first emission layer includes:
a first emission layer part on the first anode and having a top surface at a first height from a top surface of the base layer; and
a second emission layer part on the pixel definition layer and having a top surface at a second height from the top surface of the base layer higher than the first height, and
the second height of the top surface of the second emission layer part increases with decreasing distance from the partition wall.

14. A method of fabricating a display panel, the method comprising:
providing a preliminary display panel that includes a base layer, an anode on the base layer, and a preliminary pixel definition layer on the base layer and covering the anode;
forming a partition wall having a plurality of partition openings on the preliminary pixel definition layer;
forming a pixel definition layer by patterning the preliminary pixel definition layer to form a plurality of emission openings that correspondingly overlap the plurality of partition openings in a plan view and expose at least a portion of the anode;
forming a first emission layer and a first cathode in a corresponding one of the plurality of partition openings; and
forming a second emission layer and a second cathode in another corresponding one of the plurality of partition openings, wherein
the first emission layer includes a first light emitting material that generates light of a first color,
the second emission layer includes a second light emitting material that generates light of a second color different from the first color,
the first and second cathodes are in contact with the partition wall,
the first emission layer is formed by a thermal evaporation process, and
the second emission layer and the first emission layer are formed by different processes.

15. The method of claim 14, wherein the second emission layer is formed by an inkjet process.

16. The method of claim 14, wherein
the first cathode is formed by a deposition process, and
during the forming of the first emission layer and the first cathode, a deposition angle of the first emission layer and a deposition angle of the first cathode are different from each other.

17. The method of claim 14, wherein
the forming of the partition wall includes:
using a conductive material to from a first layer on the pixel definition layer;
using a material to form a second layer on the first layer, the material being different from the conductive material;
performing a first etching process in which the first layer and the second layer are patterned to form a first pattern; and
performing a second etching process in which the first layer is under-cut with respect to the second layer, and
wherein a lateral surface of the second layer protrudes from a lateral surface of the first layer and forms a tip.

18. The method of claim 14, wherein
the plurality of emission openings include a first emission opening and a second emission opening,
the method further comprises:
forming a first encapsulation pattern that covers the first emission opening; and
forming a second encapsulation pattern that covers the second emission opening, and
the first encapsulation pattern and the second encapsulation pattern are formed separated from each other.

19. The method of claim 17, wherein the first cathode and the second cathode are formed separated from each other.

20. The method of claim 14, wherein
the plurality of emission openings include a first emission opening, a second emission opening, and a third emission opening,
the method further comprises:
forming in another corresponding one of the plurality of partition openings a third emission layer including a third light emitting material that generates light of a third color different from the first color and the second color;
forming a third cathode separated from the first cathode;
forming a first encapsulation pattern that covers the first emission opening; and
forming a second encapsulation pattern that covers the second emission opening and the third emission opening and is separated from the first encapsulation pattern, and the third emission layer and the first emission layer are formed by different processes.
